(19) United States
(12) Patent Application Publication
(10) Pub. No.: US 2024/0395719 A1
(43) Pub. Date: Nov. 28, 2024

(54) SEMICONDUCTOR PACKAGE

(71) Applicant: SAMSUNG ELECTRONICS CO., LTD., Suwon-si (KR)

(72) Inventors: Hyunsoo CHUNG, Suwon-si (KR); Joonghyun BAEK, Suwon-si (KR); Inhyo HWANG, Suwon-si (KR)

(73) Assignee: SAMSUNG ELECTRONICS CO., LTD., Suwon-si (KR)

(21) Appl. No.: 18/390,834

(22) Filed: Dec. 20, 2023

(30) Foreign Application Priority Data
May 24, 2023 (KR) 10-2023-0067222

(51) Int. Cl. H01L 23/538; H01L 23/00; H01L 23/31; H01L 23/498; H01L 25/065

(52) U.S. Cl. CPC H01L 23/5381; H01L 23/3135; H01L 23/49811; H01L 23/5383; H01L 24/16; H01L 25/0652; H01L 28/40; H01L 2224/16145; H01L 2224/16225

(57) ABSTRACT

Provided is a semiconductor package including a redistribution substrate, a bridge chip on the redistribution substrate, a first conductive post and a second conductive post on the redistribution substrate and spaced apart from the bridge chip, a first semiconductor chip on the bridge chip and the first conductive post, a second semiconductor chip on the bridge chip and the second conductive post, and a first mold layer on the redistribution substrate, the bridge chip, the first semiconductor chip, and the second semiconductor chip, wherein the bridge chip includes a bridge die connected to an active surface of the first semiconductor chip and an active surface of the second semiconductor chip, a second mold layer on the bridge die, a penetration via adjacent to the bridge die and vertically penetrating the second mold layer, and a capacitor disposed a bottom surface of the second mold layer and connected to the penetration via.

### CROSS-REFERENCE TO RELATED APPLICATIONS

This U.S. non-provisional patent application claims priority to Korean Patent Application No. 10-2023-0067222, filed on May 24, 2023, in the Korean Intellectual Property Office, the disclosure of which is incorporated herein in its entirety by reference.

### BACKGROUND

Embodiments of the present disclosure relate to a semiconductor package and a method of fabricating the same, and in particular, to a semiconductor die including a bridge chip and a method of fabricating the same.

In light of recent advancements in the electronics industry, the demand for high-performance, high-speed, and compact electronic components has been steadily increasing. As a result, packaging technologies that allow mounting of multiple semiconductor chips within a single package is being developed.

A semiconductor package is configured to facilitate the use of an integrated circuit chip as a component in an electronic product. The semiconductor package includes a printed circuit board (PCB) and a semiconductor chip, which is mounted on the PCB and is electrically connected to the PCB by bonding wires or bumps. Due to recent advancements in the electronics industry, semiconductor packaging technology is evolving in diverse ways, aiming for miniaturization, weight reduction, and cost-effective manufacturing. Furthermore, as the utilization of this technology expands to different fields, including mass storage devices, several types of semiconductor packages are emerging.

### SUMMARY

One or more embodiments provide a compact semiconductor package and a method of fabricating the same.

One or more embodiments also provide a semiconductor package with improved electrical characteristics and a method of fabricating the same.

According to an aspect of an embodiment, there is provided a semiconductor package including a redistribution substrate, a bridge chip on the redistribution substrate, a first conductive post and a second conductive post on the redistribution substrate and spaced apart from the bridge chip, a first semiconductor chip on the bridge chip and the first conductive post, a second semiconductor chip on the bridge chip and the second conductive post, and a first mold layer on the redistribution substrate, the bridge chip, the first semiconductor chip, and the second semiconductor chip, wherein the bridge chip includes a bridge die connected to an active surface of the first semiconductor chip and an active surface of the second semiconductor chip, a second mold layer on the bridge die, a penetration via adjacent to the bridge die and vertically penetrating the second mold layer, and a capacitor disposed a bottom surface of the second mold layer and connected to the penetration via.

According to another aspect of an embodiment, there is provided a semiconductor package including a redistribution substrate, a bridge chip on the redistribution substrate, a first semiconductor chip and a second semiconductor chip on the bridge chip, each of the first semiconductor chip and the second semiconductor chip being shifted from the bridge chip horizontally such that a portion of an active surface of the bridge chip is exposed, and vertical connection terminals horizontally spaced apart from the bridge chip and connecting the first semiconductor chip and the second semiconductor chip to the redistribution substrate, wherein the bridge chip includes a redistribution layer on an active surface of the first semiconductor chip and an active surface of the second semiconductor chip, a bridge die on a bottom surface of the redistribution layer, a first mold layer on the bottom surface of the redistribution layer and the bridge die, a capacitor on a bottom surface of the first mold layer, and a penetration via vertically penetrating the first mold layer and connecting the redistribution layer to the capacitor.

According to another aspect of an embodiment, there is provided a semiconductor package including a first semiconductor chip and a second semiconductor chip horizontally spaced apart from each other, first sub-posts on a top surface of the first semiconductor chip and connected to the first semiconductor chip, second sub-posts on a top surface of the second semiconductor chip and connected to the second semiconductor chip, a first mold layer on the first semiconductor chip, the second semiconductor chip, the first sub-posts, and the second sub-posts, a bridge chip on the first mold layer, a portion of the first sub-posts, and a portion of the second sub-posts, a second mold layer on the first mold layer and the bridge chip, a redistribution substrate on the second mold layer and the bridge chip, first posts vertically penetrating the second mold layer and connecting a remaining portion of the first sub-posts to the redistribution substrate, and second posts vertically penetrating the second mold layer and connecting a remaining portion of the second sub-posts to the redistribution substrate, wherein the bridge chip includes a bridge die connected to a portion of the first sub-posts and a portion of the second sub-posts, a capacitor on the bridge die, and a penetration via vertically connected to the capacitor and adjacent to the bridge die.

### BRIEF DESCRIPTION OF DRAWINGS

Embodiments will be more clearly understood from the following detailed description taken in conjunction with the accompanying drawings in which:

FIG. 1 is a sectional view illustrating a semiconductor package according to an embodiment;

FIGS. 2 and 3 are sectional views, each of which illustrates a capacitor according to an embodiment;

FIG. 4 is an enlarged sectional view illustrating a portion ‘A’ of FIG. 1;

FIG. 5 is a sectional view illustrating a semiconductor package according to an embodiment;

FIGS. 6, 7, and 8 are sectional views, each of which illustrates a capacitor according to an embodiment;

FIG. 9 is a sectional view illustrating a semiconductor package according to an embodiment;

FIG. 10 is an enlarged sectional view illustrating a portion ‘B’ of FIG. 9;

FIG. 11 is a sectional view illustrating a semiconductor package according to an embodiment;

FIG. 12 is an enlarged sectional view illustrating a portion ‘C’ of FIG. 11;

FIG. 13 is a sectional view illustrating a semiconductor package according to an embodiment;

FIG. 14 is an enlarged sectional view illustrating a portion ‘D’ of FIG. 13;

FIG. 15 is a sectional view illustrating a semiconductor package according to an embodiment;

FIGS. 16, 17, 18, 19, 20, 21, 22, 23, 24, 25, 26, 27, 28, and 29 are sectional views illustrating a method of fabricating a semiconductor package, according to an embodiment.

### DETAILED DESCRIPTION

Example embodiments will now be described more fully with reference to the accompanying drawings, in which example embodiments are shown.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

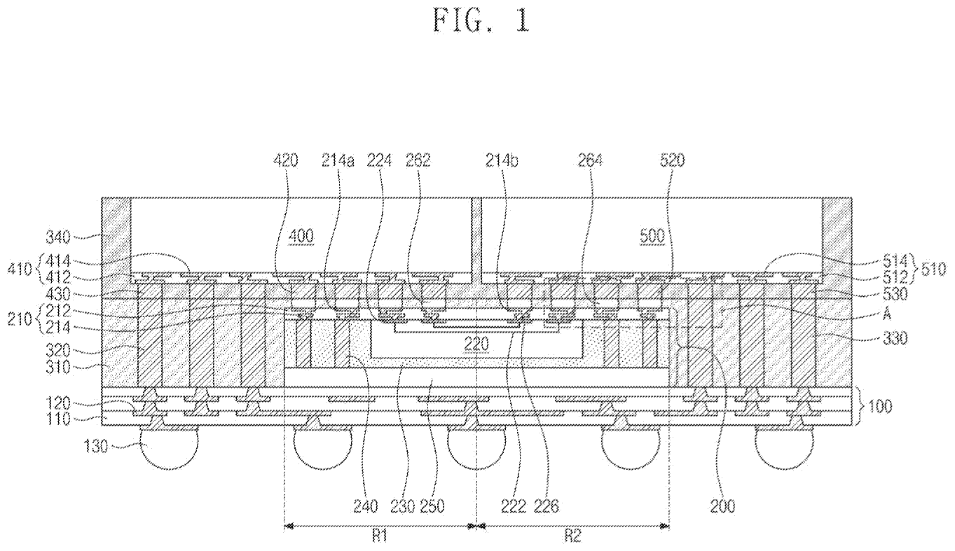

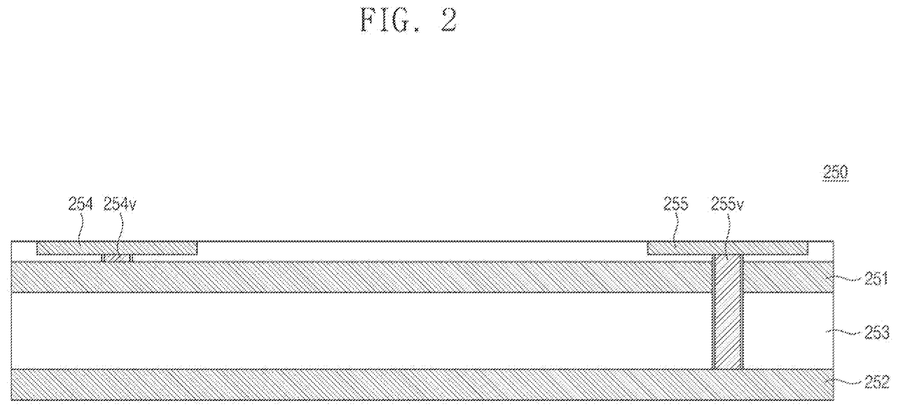

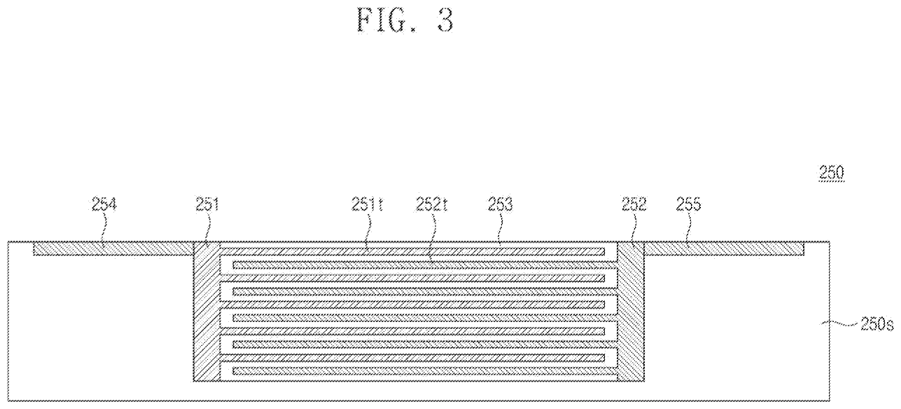

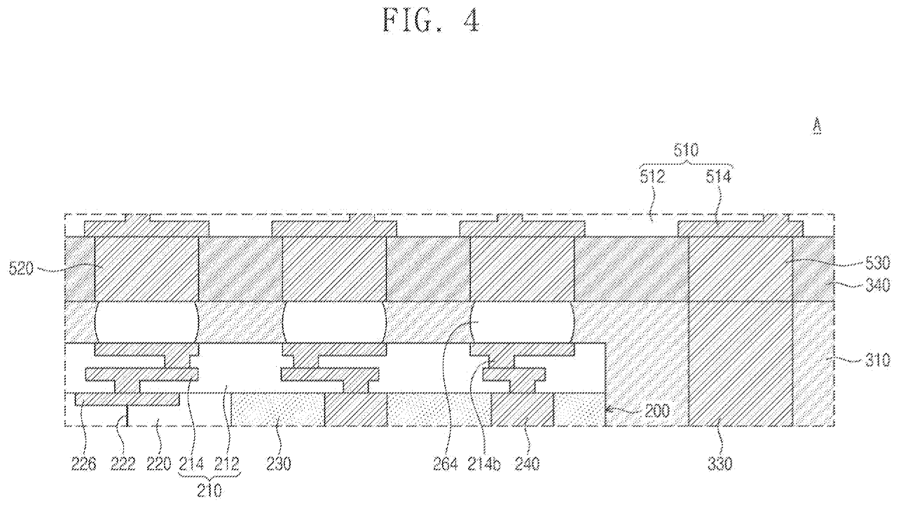

FIG. 1 is a sectional view illustrating a semiconductor package according to an embodiment. FIGS. 2 and 3 are sectional views, each of which illustrates a capacitor according to an embodiment of the inventive concept. FIG. 4 is an enlarged sectional view illustrating a portion ‘A’ of FIG. 1.

Referring to FIG. 1, a redistribution substrate 100 may be provided. The redistribution substrate 100 may include one or more interconnection layers, which are sequentially stacked. Each interconnection layer may include a first redistribution insulating layer 110 and a first redistribution conductive pattern 120 in the first redistribution insulating layer 110. In the case where a plurality of interconnection layers are provided, the first redistribution conductive pattern 120 of one interconnection layer may be electrically connected to the first redistribution conductive pattern 120 of another interconnection layer adjacent thereto.

The first redistribution insulating layer 110 may be formed of or include at least one of insulating polymers and photoimageable polymers (e.g., photoimageable dielectric (PID) materials). For example, the photoimageable dielectric materials may include at least one of photoimageable polyimide (PI), polybenzoxazole (PBO), phenol-based polymers, and benzocyclobutene-based polymers. However, embodiments are not limited thereto, and the first redistribution insulating layer 110 may include an insulating material. For example, the first redistribution insulating layer 110 may be formed of or include at least one of silicon oxide (SiO), silicon nitride (SiN), silicon oxynitride (SiON), silicon carbonitride (SiCN), and insulating polymers.

The first redistribution conductive pattern 120 may be provided on the first redistribution insulating layer 110. The first redistribution conductive pattern 120 on the first redistribution insulating layer 110 may be horizontally extended. The first redistribution conductive pattern 120 may be an element for an internal redistribution of the interconnection layer. The first redistribution conductive pattern 120 may include a conductive material. For example, the first redistribution conductive pattern 120 may be formed of or include at least one of copper (Cu) and aluminum (Al).

The first redistribution conductive pattern 120 may have a damascene structure. For example, the first redistribution conductive pattern 120 may include a head portion and a tail portion, which are connected to each other to form a single object. The head and tail portions of the first redistribution conductive pattern 120 may be provided to have a section of an inverted ‘T’ shape.

The head portion of the first redistribution conductive pattern 120 may be a wire or pad portion which is used to horizontally expand an interconnection line in the redistribution substrate 100. The head portion may be provided on a bottom surface of the first redistribution insulating layer 110. For example, the head portion may be extended to a region on the bottom surface of the first redistribution insulating layer 110 and may have a protruding shape. The first redistribution conductive pattern 120 of the lowermost one of the interconnection layers may be exposed external to the first redistribution insulating layer 110 near or from the bottom surface of the first redistribution insulating layer 110. The exposed portions of the first redistribution conductive pattern 120 may be used as pads to be connected with outer terminals 130. According to another embodiment, pads, which are connected with the outer terminals 130, may be additionally provided on a bottom surface of the redistribution substrate 100, and the pads may be connected to the exposed first redistribution conductive patterns 120.

The tail portion of the first redistribution conductive pattern 120 may be a via portion vertically connecting interconnection lines in the redistribution substrate 100 to each other. The tail portion may be connected to another interconnection layer thereon. For example, the tail portion of the first redistribution conductive pattern 120 may be extended from a top surface of the head portion to penetrate the first redistribution insulating layer 110 and may be connected to the head portion of the first redistribution conductive pattern 120 of another interconnection layer thereon. The tail portion of the first redistribution conductive pattern 120 of the uppermost one of the interconnection layers may penetrate the first redistribution insulating layer 110 and may be exposed external to the redistribution substrate 100 from a top surface of the redistribution substrate 100 (i.e., the top surface of the first redistribution insulating layer 110 of the uppermost interconnection layer). The first redistribution conductive patterns 120 of the uppermost interconnection layer may be electrically connected to first conductive posts 320 and second conductive posts 330, which will be described below.

The outer terminals 130 may be provided on the bottom surface of the redistribution substrate 100. The outer terminals 130 may be connected to the first redistribution conductive patterns 120 of the lowermost interconnection layer. The outer terminals 130 may include solder balls or solder bumps, and the semiconductor package may be a ball grid array (BGA) package, a fine ball-grid array (FBGA) package, or a land grid array (LGA) package, depending on the kind and arrangement of the outer terminals 130.

A bridge chip 200 may be disposed on the redistribution substrate 100. The bridge chip 200 may be in contact with the top surface of the redistribution substrate 100. The bridge chip 200 may have a front surface and a rear surface. Hereinafter, in the present specification, the front surface may be a surface of a semiconductor chip, which is an active surface for integrated devices, and on which interconnection lines or pads are formed, and the rear surface may be a surface that is opposite to the front surface of the semiconductor chip vertically. The rear surface of the bridge chip 200 may face the redistribution substrate 100. For example, the bridge chip 200 may be disposed on the redistribution substrate 100 in a face up manner. The bridge chip 200 may have a first region R1 and a second region R2, which are horizontally spaced apart from each other. The first region R1 may be overlapped with a first semiconductor chip 400, which will be described below, and the second region R2 may be overlapped with a second semiconductor chip 500, which will be described below. The bridge chip 200 may include a redistribution layer 210, a bridge die 220, an inner mold layer 230, a penetration vias 240, and a capacitor 250.

The redistribution layer 210 may include a second redistribution insulating layer 212 and second redistribution conductive patterns 214 in the second redistribution insulating layer 212. The second redistribution insulating layer 212 may include an insulating material. For example, the second redistribution insulating layer 212 may be formed of or include at least one of silicon oxide (SiO), silicon nitride (SiN), silicon oxynitride (SiON), silicon carbonitride (SiCN), and insulating polymers. Alternatively, the second redistribution insulating layer 212 may be formed of or include at least one of insulating polymers and photoimageable polymers (e.g., photoimageable dielectric (PID) materials). For example, the photoimageable dielectric materials may include at least one of photo-imageable polyimide (PI), polybenzoxazole (PBO), phenol-based polymers, and benzocyclobutene-based polymers. The second redistribution conductive patterns 214 may be provided in the second redistribution insulating layer 212. The second redistribution conductive patterns 214 may be used for redistribution of the bridge die 220 and the penetration vias 240. The second redistribution conductive patterns 214 may include a conductive material. For example, the second redistribution conductive patterns 214 may be formed of or include at least one of copper (Cu) and aluminum (Al). FIG. 1 illustrates an example, in which one second redistribution insulating layer 212 and the second redistribution conductive patterns 214 therein are provided, but embodiments are not limited thereto. The redistribution layer 210 may include a plurality of second redistribution insulating layers 212, and the second redistribution conductive patterns 214 may be interconnection patterns, which are horizontally or vertically extended in the second redistribution insulating layers 212. Some of the second redistribution conductive patterns 214 may be exposed external to the second redistribution insulating layer 212 near a top surface of the second redistribution insulating layer 212. The second redistribution conductive patterns 214, which are provided on the first region R1 and are exposed near the top surface of the second redistribution insulating layer 212, may serve as first pads 214a of the bridge chip 200, and the second redistribution conductive patterns 214, which are provided on the second region R2 and are exposed near the top surface of the second redistribution insulating layer 212, may serve as second pads 214b of the bridge chip 200. The first pad 214a may be a pad electrically connected to the first semiconductor chip 400, and the second pad 214b may be a pad connected to the second semiconductor chip 500.

The bridge die 220 may be disposed below the redistribution layer 210. The bridge die 220 may be in contact with a bottom surface of the redistribution layer 210. The bridge die 220 may be mounted on the bottom surface of the redistribution layer 210. For example, the bridge die 220 may have first bridge pads 224 and second bridge pads 226, which are provided on a top surface of the bridge die 220. The first bridge pads 224 may be placed on the first region R1, and the second bridge pads 226 may be disposed on the second region R2. However, embodiments are not limited thereto. At an interface between the bridge die 220 and the redistribution layer 210, the first and second bridge pads 224 and 226 may be connected to the second redistribution conductive patterns 214 of the redistribution layer 210. For example, the second redistribution conductive patterns 214 may be provided to penetrate the second redistribution insulating layer 212 and to be in contact with the first and second bridge pads 224 and 226. The first bridge pads 224 may be connected to the first pads 214a through the redistribution layer 210. The second bridge pads 226 may be connected to the second pads 214b through the redistribution layer 210. The first bridge pads 224 and the second bridge pads 226 may be connected to each other through an interconnection line 222 in the bridge die 220. The bridge die 220 may include a semiconductor material. For example, the bridge die 220 may be a semiconductor chip that is formed of silicon (Si).

The inner mold layer 230 may be disposed below the redistribution layer 210. The inner mold layer 230 may be provided on the bottom surface of the redistribution layer 210 to cover the bridge die 220. For example, the inner mold layer 230 may enclose the bridge die 220 and may cover a bottom surface of the bridge die 220. Alternatively, the inner mold layer 230 may enclose the bridge die 220 but may be provided to expose at least a portion or the entirety of the bottom surface of the bridge die 220. The inner mold layer 230 may include an insulating material. For example, the inner mold layer 230 may be formed of or include, for example, a silicon-based insulating material (e.g., silicon oxide (SiO), silicon nitride (SiN) or silicon oxynitride (SiON)) or an insulating polymer material (e.g., an epoxy molding compound (EMC)).

The capacitor 250 may be provided below the inner mold layer 230. The capacitor 250 may be in contact with a bottom surface of the inner mold layer 230. A width of the capacitor 250 may be equal to a width of the inner mold layer 230 horizontally. Side surfaces of the capacitor 250 may be vertically aligned to side surfaces of the inner mold layer 230. A bottom surface of the bridge chip 200, which is in contact with the redistribution substrate 100, may be a bottom surface of the capacitor 250. The capacitor 250 may be used to remove a noise signal, which is produced in the signal exchange operation between the first and second semiconductor chips 400 and 500, and/or to reduce the parasitic inductance and resistance between the first and second semiconductor chips 400 and 500. Hereinafter, an example structure of the capacitor 250 will be described in more detail with reference to FIGS. 2 and 3.

FIG. 2 illustrates an example of the capacitor 250, which is provided on and to cover the entire bottom surface of the inner mold layer 230. The capacitor 250 may include a first capacitor electrode 251, a second capacitor electrode 252, and a dielectric material 253, which is provided to fill a space between the first capacitor electrode 251 and the second capacitor electrode 252. The first and second capacitor electrodes 251 and 252 may be vertically spaced apart from each other. For example, the capacitor 250 may have a structure, in which the second capacitor electrode 252, the dielectric material 253, and the first capacitor electrode 251 are sequentially stacked. The first and second capacitor electrodes 251 and 252 may be formed of or include at least one of metallic materials (e.g., copper (Cu), aluminum (Al), titanium (Ti), and tungsten (W)). The dielectric material 253 may be formed of or include at least one of high-k dielectric materials (e.g., hafnium oxide (HfO)).

The capacitor 250 may have a first capacitor pad 254 and a second capacitor pad 255, which are provided on a top surface of the capacitor 250. The first capacitor electrode 251 may be electrically connected to the first capacitor pad 254 through a first capacitor via 254v, which is provided between the first capacitor pad 254 and the first capacitor electrode 251. The first capacitor via 254v may be extended from a bottom surface of the first capacitor pad 254 and may be connected to a top surface of the first capacitor electrode 251. The second capacitor electrode 252 may be electrically connected to the second capacitor pad 255 through a second capacitor via 255v, which is provided between the second capacitor pad 255 and the second capacitor electrode 252. The second capacitor via 255v may be extended from a bottom surface of the second capacitor pad 255 to penetrate the first capacitor electrode 251 and the dielectric material 253 and may be connected to a top surface of the second capacitor electrode 252. The first capacitor via 254v and the second capacitor via 255v may be formed of or include at least one of conductive materials. In an embodiment, at least one insulating layer may be further provided to enclose each of the first and second capacitor vias 254v and 255v.

In an embodiment, the capacitor 250 may be provided in a recess, which is formed on a front surface of a substrate 250s. FIG. 3 illustrates another example of the capacitor 250 with the substrate 250s. The substrate 250s may include a silicon substrate or an insulating substrate. The recess may be formed on a top surface of the inner mold layer 230. The capacitor 250 may include the first and second capacitor electrodes 251 and 252, which are provided in the recess and are horizontally spaced apart from each other, and the dielectric material 253, which is provided to fill a space between the first and second capacitor electrodes 251 and 252.

The first and second capacitor electrodes 251 and 252 may be respectively connected to the first and second capacitor pads 254 and 255 of the capacitor 250. Each of the first and second capacitor pads 254 and 255 may be an interconnection line or a pad, which is formed near the top surface of the capacitor 250. On or near the top surface of the capacitor 250, each of the first and second capacitor pads 254 and 255 may be extended toward the recess to be in contact with the first and second capacitor electrodes 251 and 252.

In order to increase an electrostatic capacitance of the capacitor 250, the capacitor 250 may further include first sub-electrodes 251t and second sub-electrodes 252t, which are alternatively provided between the first and second capacitor electrodes 251 and 252. The first sub-electrodes 251t may be connected to the first capacitor electrode 251, and the second sub-electrodes 252t may be connected to the second capacitor electrode 252.

Examples of the capacitor 250 have been described, but embodiments are not limited thereto. In an embodiment, various capacitors, resistors, or inductors may be provided in place of the capacitor 250.

Referring back to FIG. 1, the penetration vias 240 may be provided in the inner mold layer 230. The penetration vias 240 may be horizontally spaced apart from the bridge die 220. The penetration vias 240 may have a pillar shape. The penetration vias 240 may be provided to vertically penetrate the inner mold layer 230. For example, the penetration vias 240 may be extended toward the top surface of the inner mold layer 230 and may be connected to the second redistribution conductive patterns 214 of the redistribution layer 210. The penetration vias 240 may be extended toward the bottom surface of the inner mold layer 230 and may be connected to the first and second capacitor pads 254 and 255 of the capacitor 250. The capacitor 250 may be connected to the first and second pads 214a and 214b through the penetration vias 240 and the redistribution layer 210. The penetration vias 240 may include a conductive material. For example, the penetration vias 240 may be formed of or include a metallic material (e.g., copper (Cu) or tungsten (W)).

Connection terminals 262 and 264 may be provided on the bridge chip 200. For example, the connection terminals 262 and 264 may include first connection terminals 262, which are provided on the first pads 214a of the redistribution layer 210 of the bridge chip 200, and second connection terminals 264, which are provided on the second pads 214b of the redistribution layer 210. The first connection terminals 262 may be configured to connect the bridge chip 200 to the first semiconductor chip 400, and the second connection terminals 264 may be configured to connect the bridge chip 200 to the second semiconductor chip 500. The connection terminals 262 and 264 may include solder balls or solder bumps.

A first mold layer 310 may be provided on the redistribution substrate 100. The first mold layer 310 on the redistribution substrate 100 may enclose the bridge chip 200. The first mold layer 310 may cover the bridge chip 200. Here, the first mold layer 310 may be provided on the bridge chip 200 to enclose the connection terminals 262 and 264. The connection terminals 262 and 264 may not be covered with the first mold layer 310 and may be exposed external to the first mold layer 310 near a top surface of the first mold layer 310. The first mold layer 310 may include an insulating material. For example, the first mold layer 310 may be formed of or include an insulating polymer material (e.g., an epoxy molding compound (EMC)).

Conductive posts 320 and 330 may be provided on the redistribution substrate 100. For example, the conductive posts 320 and 330 may include first conductive posts 320, which are adjacent to the first region R1 of the bridge chip 200, and second conductive posts 330, which are adjacent to the second region R2 of the bridge chip 200. The first conductive posts 320 may be vertical connection structures, which are configured to connect the first semiconductor chip 400 to the redistribution substrate 100, and the second conductive posts 330 may be vertical connection structures, which are configured to connect the second semiconductor chip 500 to the redistribution substrate 100. The conductive posts 320 and 330 may be horizontally spaced apart from the bridge chip 200. The conductive posts 320 and 330 may have a pillar shape. The conductive posts 320 and 330 may be provided to vertically penetrate the first mold layer 310. For example, the conductive posts 320 and 330 may be extended toward the top surface of the first mold layer 310 and may be exposed external to the first mold layer 310. The conductive posts 320 and 330 may be extended toward a bottom surface of the first mold layer 310 and may be connected to the first redistribution conductive pattern 120 of the redistribution substrate 100. The conductive posts 320 and 330 may include a conductive material. For example, the conductive posts 320 and 330 may be formed of or include a metallic material (e.g., copper (Cu) or tungsten (W)).

Referring to FIGS. 1 and 4, the first semiconductor chip 400 may be provided on the first mold layer 310. A portion of the first semiconductor chip 400 may be vertically overlapped with the first region R1 of the bridge chip 200. For example, the first semiconductor chip 400 may be placed on the first region R1 of the bridge chip 200 and may be horizontally shifted from the bridge chip 200. For example, the bridge chip 200 and the first semiconductor chip 400 may be stacked vertically and offset horizontally. The portion of the first semiconductor chip 400 may be placed on the first region R1 of the bridge chip 200, and a remaining portion of the first semiconductor chip 400 may be placed on a region beside the bridge chip 200. The remaining portion of the first semiconductor chip 400 may be placed on the first conductive posts 320. When the semiconductor package is viewed from its bottom surface, a bottom surface of the first semiconductor chip 400 may have an exposed portion that is not covered by the bridge chip 200. The first semiconductor chip 400 may be formed of or include a semiconductor material (e.g., silicon (Si)). The first semiconductor chip 400 may include a first integrated circuit, which is provided on the bottom surface of the first semiconductor chip 400. The first integrated circuit may include a logic circuit or a memory circuit. For example, the first semiconductor chip 400 may be a logic chip or a memory chip. However, embodiments are not limited thereto, and the first semiconductor chip 400 may include a logic chip, a memory chip, a semiconductor chip with other integrated circuit, or a passive device. The bottom surface of the first semiconductor chip 400 may be an active surface, and the top surface of the first semiconductor chip 400 may be an inactive surface. For example, the first semiconductor chip 400 may be disposed on the first mold layer 310 in a face down manner such that the active surface of the first semiconductor chip 400 faces downward the first mold layer 310.

The first semiconductor chip 400 may include a first circuit layer 410. The first circuit layer 410 may be provided on the bottom surface of the first semiconductor chip 400. The first circuit layer 410 may include a first chip insulating layer 412 and a first chip interconnection pattern 414 in the first chip insulating layer 412. The first chip insulating layer 412 on the bottom surface of the first semiconductor chip 400 may cover the first integrated circuit. The first chip insulating layer 412 may be formed of or include an insulating material (e.g., silicon oxide (SiO), silicon nitride (SiN), or silicon oxynitride (SiON)). The first chip interconnection pattern 414 may be electrically connected to the first integrated circuit. The first chip interconnection pattern 414 may be exposed external to the first chip insulating layer 412 near a bottom surface of the first chip insulating layer 412 and may be used as a pad of the first semiconductor chip 400.

First sub-posts 420 and the second sub-posts 430 may be provided on the bottom surface of the first semiconductor chip 400. The first sub-posts 420 may be provided between the first semiconductor chip 400 and the bridge chip 200. For example, the first sub-posts 420 may be interposed between the first chip interconnection pattern 414 of the first semiconductor chip 400 and the first connection terminals 262. The second sub-posts 430 may be provided between the first semiconductor chip 400 and the first conductive posts 320. For example, the second sub-posts 430 may be interposed between the first chip interconnection pattern 414 of the first semiconductor chip 400 and the first conductive posts 320. FIGS. 1 and 4 illustrate an example, in which the first and second sub-posts 420 and 430 are pillar-shaped posts, but embodiments are not limited thereto. For example, a conductive structure (e.g., solder bumps) may be provided instead of the first and second sub-posts 420 and 430.

The first semiconductor chip 400 may be mounted on the bridge chip 200 and the first conductive posts 320 using the first and second sub-posts 420 and 430. For example, the first sub-posts 420 may connect the first chip interconnection pattern 414 to the first connection terminals 262, and the second sub-posts 430 may connect the first chip interconnection pattern 414 to the first conductive posts 320. The first semiconductor chip 400 may be electrically connected to the bridge die 220 through the first sub-posts 420, the first connection terminals 262, and the redistribution layer 210, may be electrically connected to the capacitor 250 through the first sub-posts 420, the first connection terminals 262, the redistribution layer 210, and the penetration vias 240, and may be electrically connected to the redistribution substrate 100 through the second sub-posts 430 and the first conductive posts 320.

The second semiconductor chip 500 may be provided on the first mold layer 310. The second semiconductor chip 500 may be horizontally spaced apart from the first semiconductor chip 400. A portion of the second semiconductor chip 500 may be vertically overlapped with the second region R2 of the bridge chip 200. For example, the second semiconductor chip 500 may be placed on the second region R2 of the bridge chip 200 and may be horizontally shifted from the bridge chip 200. For example, the bridge chip 200 and the second semiconductor chip 500 may be vertically stacked and horizontally offset. The portion of the second semiconductor chip 500 may be placed on the second region R2 of the bridge chip 200, and a remaining portion of the second semiconductor chip 500 may be placed on a region beside the bridge chip 200. The remaining portion of the second semiconductor chip 500 may be placed on the second conductive posts 330. When the semiconductor package is viewed from its bottom surface, a bottom surface of the second semiconductor chip 500 may have an exposed portion that is not covered by the bridge chip 200. The bridge chip 200 may be overlapped with both of a portion of the first semiconductor chip 400 and a portion of the second semiconductor chip 500. The second semiconductor chip 500 may be formed of or include a semiconductor material (e.g., silicon (Si)). The second semiconductor chip 500 may include a second integrated circuit, which is provided on the bottom surface of the second semiconductor chip 500. The second integrated circuit may include a logic circuit or a memory circuit. For example, the second semiconductor chip 500 may be a logic chip or a memory chip. However, embodiments are not limited thereto, and the second semiconductor chip 500 may include a logic chip, a memory chip, a semiconductor chip with other integrated circuit, or a passive device. The second semiconductor chip 500 may be of the same kind as or a different kind from the first semiconductor chip 400. The bottom surface of the second semiconductor chip 500 may be an active surface, and the top surface of the second semiconductor chip 500 may be an inactive surface. For example, the second semiconductor chip 500 may be disposed on the first mold layer 310 in a face down manner.

The second semiconductor chip 500 may include a second circuit layer 510. The second circuit layer 510 may be provided on the bottom surface of the second semiconductor chip 500. The second circuit layer 510 may include a second chip insulating layer 512 and a second chip interconnection pattern 514 in the second chip insulating layer 512. The second chip insulating layer 512 may be provided on the bottom surface of the second semiconductor chip 500 to cover the second integrated circuit. The second chip insulating layer 512 may be formed of or include an insulating material (e.g., silicon oxide (SiO), silicon nitride (SiN), or silicon oxynitride (SiON)). The second chip interconnection pattern 514 may be electrically connected to the second integrated circuit. The second chip interconnection pattern 514 may be exposed external to the second chip insulating layer 512 near a bottom surface of the second chip insulating layer 512 and may be used as a pad of the second semiconductor chip 500.

Third sub-posts 520 and the fourth sub-posts 530 may be provided on the bottom surface of the second semiconductor chip 500. The third sub-posts 520 may be provided between the second semiconductor chip 500 and the bridge chip 200. For example, the third sub-posts 520 may be interposed between the second chip interconnection pattern 514 of the second semiconductor chip 500 and the second connection terminals 264. The fourth sub-posts 530 may be provided between the second semiconductor chip 500 and the second conductive posts 330. For example, the fourth sub-posts 530 may be interposed between the second chip interconnection pattern 514 of the second semiconductor chip 500 and the second conductive posts 330. FIGS. 1 and 4 illustrate an example, in which the third and fourth sub-posts 520 and 530 are pillar-shaped posts, but embodiments are not limited thereto. A conductive structure (e.g., solder bumps) may be provided instead of the third and fourth sub-posts 520 and 530.

The second semiconductor chip 500 may be mounted on the bridge chip 200 and the second conductive posts 330 using the third and fourth sub-posts 520 and 530. For example, the third sub-posts 520 may connect the second chip interconnection pattern 514 to the second connection terminals 264, and the fourth sub-posts 530 may connect the second chip interconnection pattern 514 to the second conductive posts 330. The second semiconductor chip 500 may be electrically connected to the bridge die 220 through the third sub-posts 520, the second connection terminals 264, and the redistribution layer 210, may be electrically connected to the capacitor 250 through the third sub-posts 520, the second connection terminals 264, the redistribution layer 210, and the penetration vias 240, and may be electrically connected to the redistribution substrate 100 through the fourth sub-posts 530 and the second conductive posts 330. The bridge die 220 may electrically connect the first semiconductor chip 400 to the second semiconductor chip 500.

According to an embodiment, since the capacitor 250 is provided in the bridge chip 200 connecting the first semiconductor chip 400 to the second semiconductor chip 500, it may be possible to omit an additional space for a capacitor device from the semiconductor package. For example, it may be possible to reduce a size of the semiconductor package. Furthermore, since not only the bridge die 220 for connecting the first semiconductor chip 400 to the second semiconductor chip 500 but also the capacitor 250 connected to the first and second semiconductor chips 400 and 500 are provided in the bridge chip 200, it may be possible to reduce lengths of electric connection paths between the bridge die 220, the capacitor 250, and the first and second semiconductor chips 400 and 500. As a result, a semiconductor package with improved electrical characteristics may be provided.

Referring back to FIG. 1, a second mold layer 340 may be provided on the first mold layer 310. The second mold layer 340 on the first mold layer 310 may be provided to enclose the first and second semiconductor chips 400 and 500. The second mold layer 340 may be provided to expose the top surface of the first semiconductor chip 400 and the top surface of the second semiconductor chip 500. According to another embodiment, the first and second semiconductor chips 400 and 500 may be covered with the second mold layer 340. The second mold layer 340 may be provided below the first semiconductor chip 400 to enclose the first and second sub-posts 420 and 430 and may be provided below the second semiconductor chip 500 to enclose the third and fourth sub-posts 520 and 530. The first to fourth sub-posts 420, 430, 520, and 530 may not be covered with the second mold layer 340 and may be exposed external to the second mold layer 340 near or on the bottom surface of the second mold layer 340. The bottom surface of the second mold layer 340 may be coplanar with bottom surfaces of the first to fourth sub-posts 420, 430, 520, and 530. An interface between the first mold layer 310 and the second mold layer 340 may be coplanar with an interface between the first conductive posts 320 and the second sub-posts 430, an interface between the first connection terminals 262 and the first sub-posts 420, an interface between the second connection terminals 264 and the third sub-posts 520, and an interface between the second conductive posts 330 and the fourth sub-posts 530. The second mold layer 340 may include an insulating material. For example, the second mold layer 340 may be formed of or include an insulating polymer material (e.g., an epoxy molding compound (EMC)).

Hereinafter, an element previously described with reference to FIGS. 1 to 4 may be identified by the same reference number without repeating an overlapping description thereof, for convenience in description. For example, technical features, which are different from those in the embodiments of FIGS. 1 to 4, will be mainly described below.

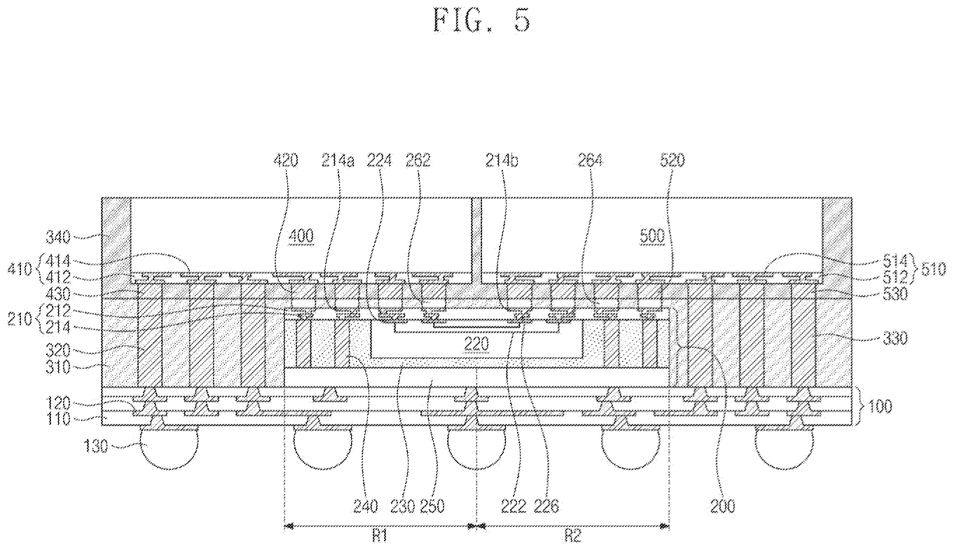

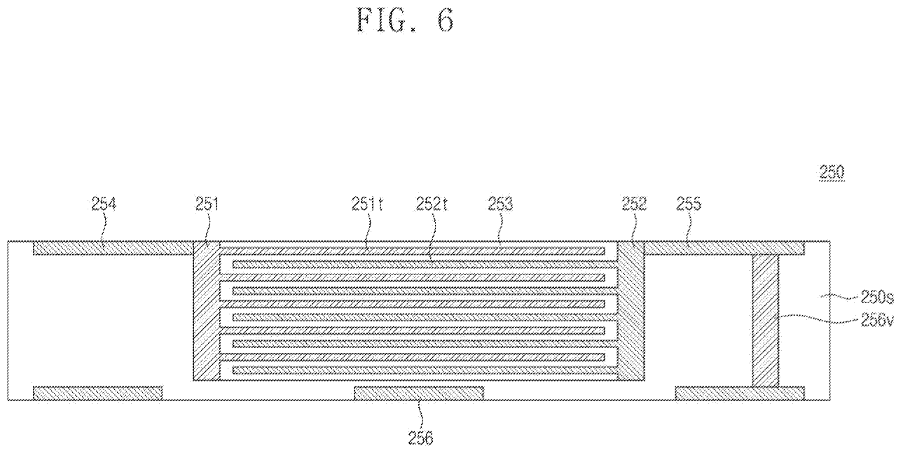

FIG. 5 is a sectional view illustrating a semiconductor package according to an embodiment. FIGS. 6 to 8 are sectional views, each of which illustrates a capacitor according to an embodiment.

In the embodiment of FIGS. 1 to 4, the capacitor 250 of the bridge chip 200 is illustrated to be directly connected only to the penetration vias 240 and not to the redistribution substrate 100, but embodiments are not limited thereto.

Referring to FIG. 5, the redistribution substrate 100 may be provided. The redistribution substrate 100 may include a plurality of interconnection layers. At least a portion of the first redistribution conductive pattern 120 of the uppermost one of the interconnection layers may be exposed external to the first redistribution insulating layer 110 near the top surface of the first redistribution insulating layer 110 and may be electrically connected to the capacitor 250 of the bridge chip 200. For this, the capacitor 250 may have pads provided on a bottom surface thereof. Hereinafter, example structures of the capacitor 250 will be described For example with reference to FIGS. 6 to 8.

FIG. 6 illustrates an example of the capacitor 250, which is provided in a recess formed in the top surface of the capacitor 250. The capacitor 250 of FIG. 6 may have a structure For example similar to the capacitor 250 of FIG. 3 and may further include third capacitor pads 256 and a third capacitor via 256v. The third capacitor pads 256 may be provided on the bottom surface of the capacitor 250 and may be used to connect the capacitor 250 to the redistribution substrate 100. The third capacitor pads 256 may be electrically connected to the second capacitor pad 255 through the third capacitor via 256v, which is provided between the second capacitor pad 255 and the third capacitor pads 256. The third capacitor via 256v may be provided near the recess to vertically penetrate the substrate 250s and connect the second capacitor pad 255 to the third capacitor pads 256.

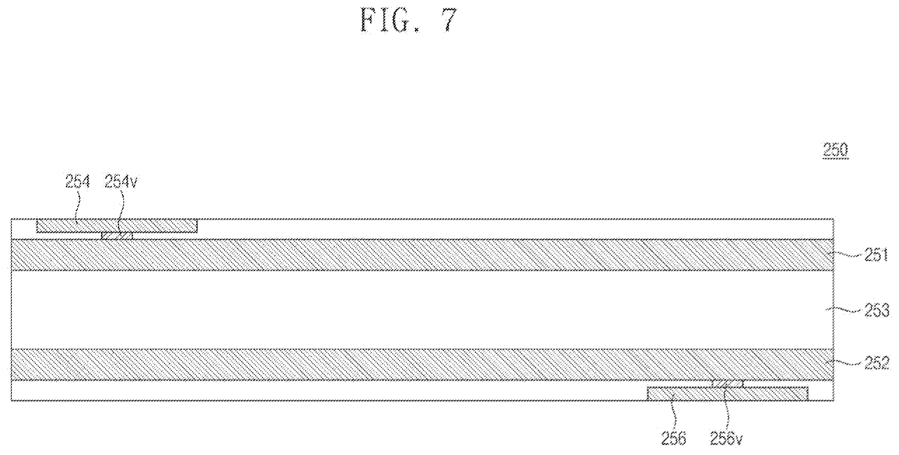

FIG. 7 illustrates another example of the capacitor 250, which is provided on and to cover the entire bottom surface of the inner mold layer 230. The capacitor 250 of FIG. 7 may have a structure For example similar to the capacitor 250 of FIG. 2 but includes the third capacitor pad 256, which is provided in place of the second capacitor pad 255. The second capacitor electrode 252 may be electrically connected to the third capacitor pad 256 through the third capacitor via 256v, which is provided between the third capacitor pad 256 and the second capacitor electrode 252. The third capacitor via 256v may be extended from a top surface of the third capacitor pad 256 and may be connected to a bottom surface of the second capacitor electrode 252.

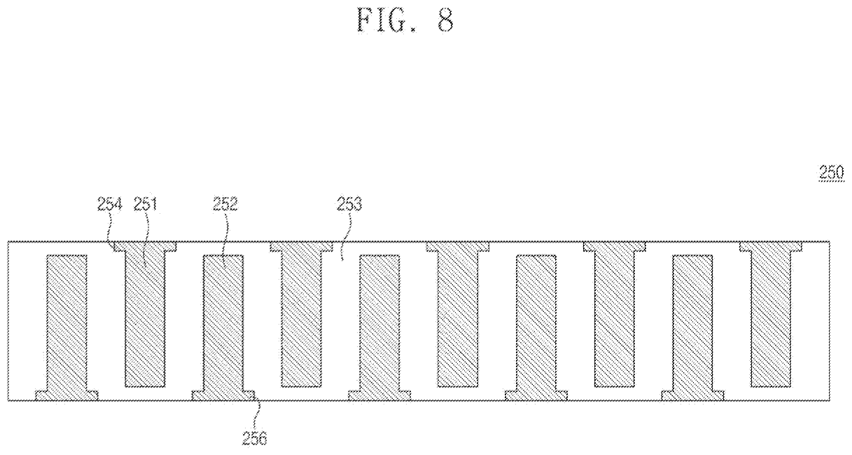

FIG. 8 illustrates still another example of the capacitor 250, which includes the first capacitor electrodes 251, which are extended from the top surface of the capacitor 250 into the capacitor 250 and have a pillar shape, the second capacitor electrodes 252, which are extended from the bottom surface of the capacitor 250 into the capacitor 250 and have a pillar shape, and the dielectric material 253, which is provided to fill a space between the first capacitor electrodes 251 and the second capacitor electrodes 252. Portions of the first capacitor electrodes 251, which are exposed to the outside near or on the top surface of the capacitor 250, may serve as the first capacitor pads 254 of the capacitor 250, and portions of the second capacitor electrodes 252, which are exposed to the outside near the bottom surface of the capacitor 250, may serve as the third capacitor pads 256 of the capacitor 250.

Referring back to FIG. 5, the penetration vias 240 of the bridge chip 200 may be connected to the first and second capacitor pads 254 and 255 of the capacitor 250. The first redistribution conductive pattern 120 of the redistribution substrate 100 may be connected to the third capacitor pads 256 of the capacitor 250.

According to an embodiment, the first and second semiconductor chips 400 and 500 may be connected to the redistribution substrate 100 through the first and second conductive posts 320 and 330 as well as the bridge chip 200. For example, the number of electric connection paths between the first and second semiconductor chips 400 and 500 and the redistribution substrate 100 may be increased, and in this case, it may be possible to improve the electrical characteristics of the semiconductor package.

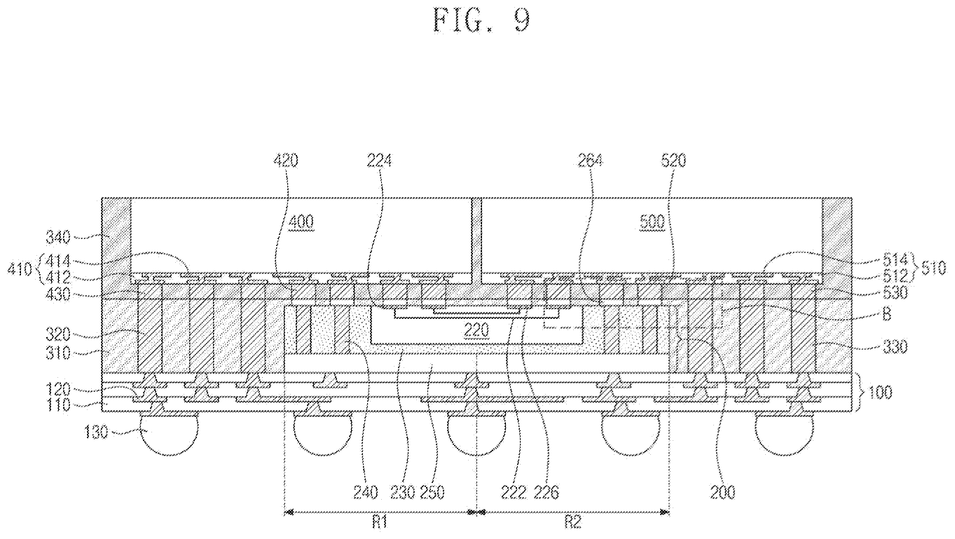

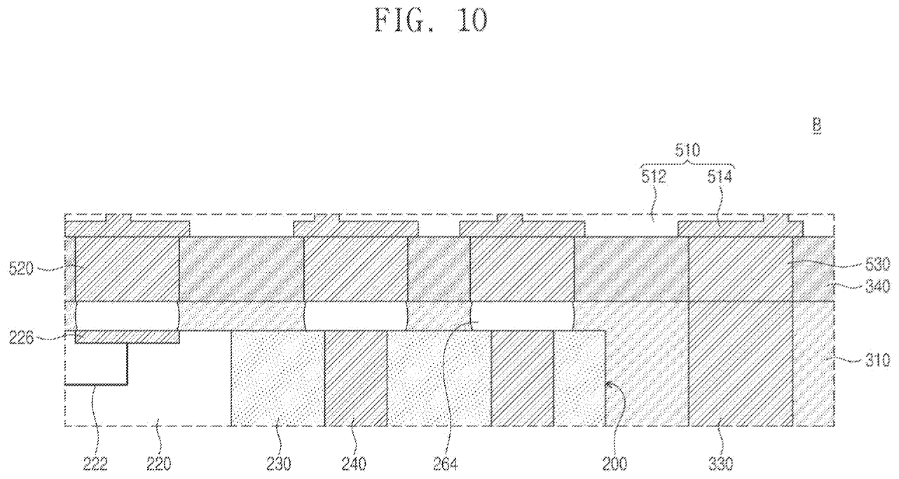

FIG. 9 is a sectional view illustrating a semiconductor package according to an embodiment. FIG. 10 is an enlarged sectional view illustrating a portion ‘B’ of FIG. 9.

Referring to FIGS. 9 and 10, the bridge chip 200 may not include the redistribution layer 210.

The connection terminals 262 and 264 may be provided on the bridge chip 200. For example, the first connection terminals 262 may be provided on the first bridge pads 224 of the bridge die 220 of the bridge chip 200. In addition, the first connection terminals 262 may be provided on the penetration vias 240 positioned on the first region R1. The second connection terminals 264 may be provided on the second bridge pads 226 of the bridge die 220 of the bridge chip 200. Furthermore, the second connection terminals 264 may be provided on the penetration vias 240 positioned on the second region R2.

The first mold layer 310 may be provided on the redistribution substrate 100 to cover the bridge chip 200. For example, the first mold layer 310 may cover the inner mold layer 230 and the bridge die 220 of the bridge chip 200. Here, the first mold layer 310 may be provided on the bridge chip 200 to enclose the connection terminals 262 and 264, and here, top surfaces of the connection terminals 262 and 264 may be exposed external to the first mold layer 310 near the top surface of the first mold layer 310.

The first semiconductor chip 400 may be mounted on the bridge chip 200 and the first conductive posts 320 using the first and second sub-posts 420 and 430. The first semiconductor chip 400 may be electrically connected to the bridge die 220 through the first sub-posts 420 and the first connection terminals 262, may be electrically connected to the capacitor 250 through the first sub-posts 420, the first connection terminals 262, and the penetration vias 240, and may be electrically connected to the redistribution substrate 100 through the second sub-posts 430 and the first conductive posts 320.

The second semiconductor chip 500 may be mounted on the bridge chip 200 and the second conductive posts 330 using the third and fourth sub-posts 520 and 530. The second semiconductor chip 500 may be electrically connected to the bridge die 220 through the third sub-posts 520 and the second connection terminals 264, may be electrically connected to the capacitor 250 through the third sub-posts 520, the second connection terminals 264, and the penetration vias 240, and may be electrically connected to the redistribution substrate 100 through the fourth sub-posts 530 and the second conductive posts 330.

According to an embodiment, a length of an electric connection path between the first and second semiconductor chips 400 and 500 and the bridge die 220 may be reduced. As a result, a semiconductor package with improved electrical characteristics may be provided.

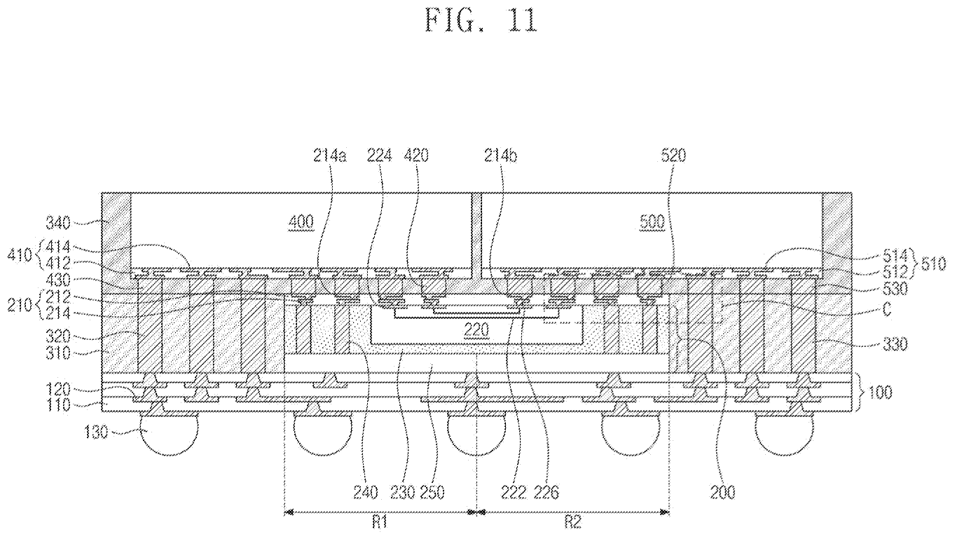

FIG. 11 is a sectional view illustrating a semiconductor package according to an embodiment. FIG. 12 is an enlarged sectional view illustrating a portion ‘C’ of FIG. 11.

Referring to FIGS. 11 and 12, a semiconductor package may not include the connection terminals 262 and 264.

The first mold layer 310 may be provided on the redistribution substrate 100 to enclose the bridge chip 200. The first mold layer 310 may not cover a top surface of the bridge chip 200. For example, a top surface of the redistribution layer 210 of the bridge chip 200 may not be covered with the first mold layer 310 and may be exposed external to the first mold layer 310 near the top surface of the first mold layer 310. The top surface of the redistribution layer 210 may be coplanar with the top surface of the first mold layer 310.

The first and second sub-posts 420 and 430 may be provided on the bottom surface of the first semiconductor chip 400. The first sub-posts 420 may be interposed between the first chip interconnection pattern 414 of the first semiconductor chip 400 and the first pads 214a of the bridge chip 200. The second sub-posts 430 may be interposed between the first chip interconnection pattern 414 of the first semiconductor chip 400 and the first conductive posts 320.

The first semiconductor chip 400 may be mounted on the bridge chip 200 and the first conductive posts 320 using the first and second sub-posts 420 and 430. For example, the first sub-posts 420 may connect the first chip interconnection pattern 414 to the first pads 214a of the bridge chip 200, and the second sub-posts 430 may connect the first chip interconnection pattern 414 to the first conductive posts 320. Here, the first sub-posts 420 and the first pads 214a may form an inter-metal hybrid bonding structure. In the present specification, the hybrid bonding structure may be a bonding structure which is formed by two materials, which are of the same kind and are fused at an interface therebetween. For example, the first sub-posts 420 and the first pads 214a, which are bonded to each other, may have a continuous structure, and there may be no visible or observable interface between the first sub-posts 420 and the first pads 214a. For example, the first sub-posts 420 and the first pads 214a may be formed of the same material and may be provided in the form of a single object. For example, the first sub-posts 420 and the first pads 214a may be bonded to form a single object. The first semiconductor chip 400 may be electrically connected to the bridge die 220 through the first sub-posts 420 and the redistribution layer 210, may be electrically connected to the capacitor 250 through the first sub-posts 420, the redistribution layer 210, and the penetration vias 240, and may be electrically connected to the redistribution substrate 100 through the second sub-posts 430 and the first conductive posts 320.

The third and fourth sub-posts 520 and 530 may be provided on the bottom surface of the second semiconductor chip 500. The third sub-posts 520 may be interposed between the second chip interconnection pattern 514 of the second semiconductor chip 500 and the second pads 214b of the bridge chip 200. The fourth sub-posts 530 may be interposed between the second chip interconnection pattern 514 of the second semiconductor chip 500 and the second conductive posts 330.

The second semiconductor chip 500 may be mounted on the bridge chip 200 and the second conductive posts 330 using the third and fourth sub-posts 520 and 530. For example, the third sub-posts 520 may connect the second chip interconnection pattern 514 to the second pads 214b of the bridge chip 200, and the fourth sub-posts 530 may connect the second chip interconnection pattern 514 to the second conductive posts 330. Here, the third sub-posts 520 and the second pads 214b may form an inter-metal hybrid bonding structure. For example, the third sub-posts 520 and the second pads 214b, which are bonded to each other, may have a continuous structure, and there may be no visible or observable interface between the third sub-posts 520 and the second pads 214b. For example, the third sub-posts 520 and the second pads 214b may be integrally formed of the same material and may be provided in the form of a single object. For example, the third sub-posts 520 and the second pads 214b may be bonded to form a single object. The second semiconductor chip 500 may be electrically connected to the bridge die 220 through the third sub-posts 520 and the redistribution layer 210, may be electrically connected to the capacitor 250 through the third sub-posts 520, the redistribution layer 210, and the penetration vias 240, and may be electrically connected to the redistribution substrate 100 through the fourth sub-posts 530 and the second conductive posts 330. The bridge die 220 may electrically connect the first semiconductor chip 400 to the second semiconductor chip 500.

According to an embodiment, a length of an electric connection path between the first and second semiconductor chips 400 and 500 and the bridge die 220 may be reduced. As a result, a semiconductor package with improved electrical characteristics may be provided. In addition, since the pads 214a and 214b of the redistribution layer 210 of the bridge chip 200 are directly bonded to the first and third sub-posts 420 and 520, the semiconductor package may have improved structural stability.

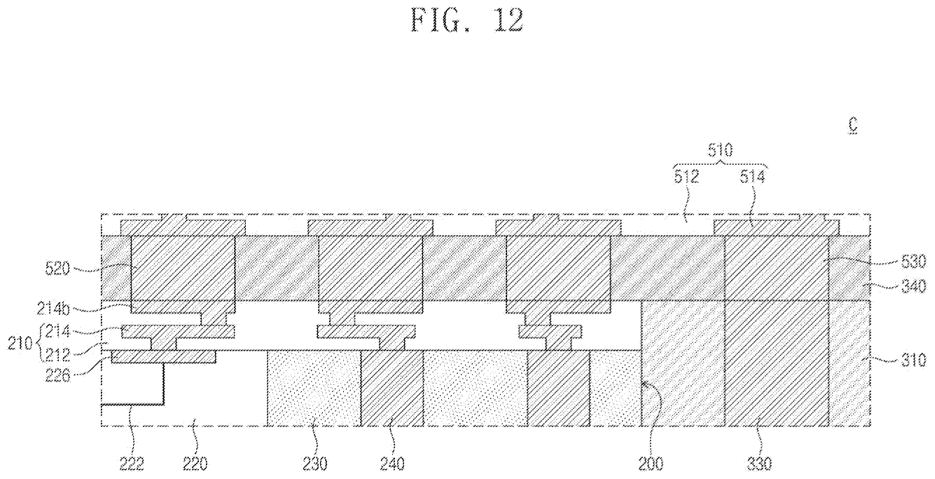

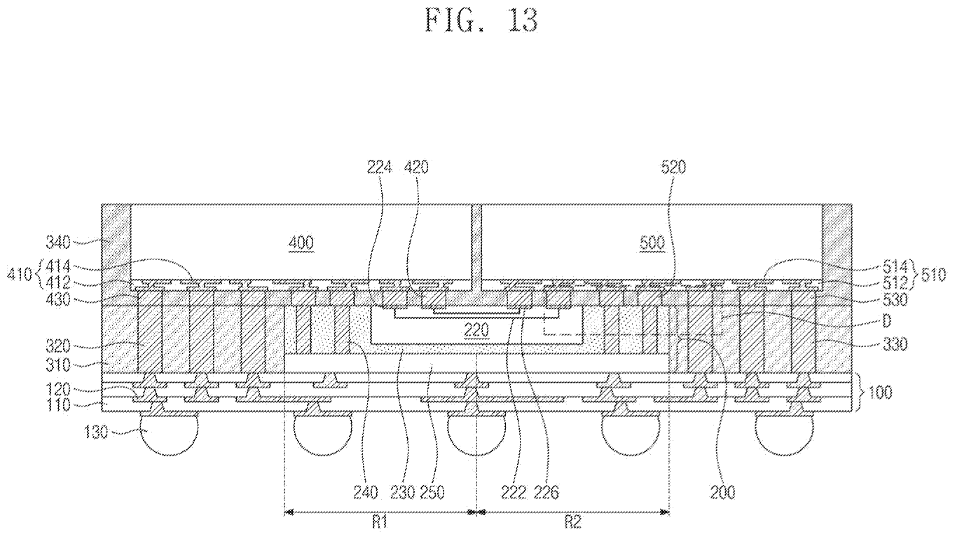

FIG. 13 is a sectional view illustrating a semiconductor package according to an embodiment. FIG. 14 is an enlarged sectional view illustrating a portion ‘D’ of FIG. 13.

Referring to FIGS. 13 and 14, a semiconductor package may not include the connection terminals 262 and 264, and the bridge chip 200 may not include the redistribution layer 210.

The first mold layer 310 may be provided on the redistribution substrate 100 to enclose the bridge chip 200. The first mold layer 310 may not cover the top surface of the bridge chip 200. For example, the top surface of the inner mold layer 230 of the bridge chip 200 and the top surface of the bridge die 220 may not be covered with the first mold layer 310 and may be exposed external to the first mold layer 310 near the top surface of the first mold layer 310. The top surface of the inner mold layer 230, the top surface of the bridge die 220, and the top surface of the first mold layer 310 may be substantially coplanar with each other.

The first and second sub-posts 420 and 430 may be provided on the bottom surface of the first semiconductor chip 400. The first sub-posts 420 may be interposed between the first chip interconnection pattern 414 of the first semiconductor chip 400 and the first bridge pads 224 of the bridge die 220. The second sub-posts 430 may be interposed between the first chip interconnection pattern 414 of the first semiconductor chip 400 and the first conductive posts 320.

The first semiconductor chip 400 may be mounted on the bridge chip 200 and the first conductive posts 320 using the first and second sub-posts 420 and 430. For example, the first sub-posts 420 may connect the first chip interconnection pattern 414 to the first bridge pads 224, and the second sub-posts 430 may connect the first chip interconnection pattern 414 to the first conductive posts 320. Here, the first sub-posts 420 and the first bridge pads 224 may form an inter-metal hybrid bonding structure. For example, the first sub-posts 420 and the first bridge pads 224, which are bonded to each other, may have a continuous structure, and there may be no visible or observable interface between the first sub-posts 420 and the first bridge pads 224. For example, the first sub-posts 420 and the first bridge pads 224 may be formed of the same material and may be provided in the form of a single object. For example, the first sub-posts 420 and the first bridge pads 224 may be bonded to form a single object. The first semiconductor chip 400 may be electrically connected to the bridge die 220 through the first sub-posts 420, may be electrically connected to the capacitor 250 through the first sub-posts 420 and the penetration vias 240, and may be electrically connected to the redistribution substrate 100 through the second sub-posts 430 and the first conductive posts 320.

The third and fourth sub-posts 520 and 530 may be provided on the bottom surface of the second semiconductor chip 500. The third sub-posts 520 may be interposed between the second chip interconnection pattern 514 of the second semiconductor chip 500 and the second bridge pads 226 of the bridge die 220. The fourth sub-posts 530 may be interposed between the second chip interconnection pattern 514 of the second semiconductor chip 500 and the second conductive posts 330.

The second semiconductor chip 500 may be mounted on the bridge chip 200 and the second conductive posts 330 using the third and fourth sub-posts 520 and 530. For example, the third sub-posts 520 may connect the second chip interconnection pattern 514 to the second bridge pads 226, and the fourth sub-posts 530 may connect the second chip interconnection pattern 514 to the second conductive posts 330. Here, the third sub-posts 520 and the second bridge pads 226 may form an inter-metal hybrid bonding structure. For example, the third sub-posts 520 and the second bridge pads 226, which are bonded to each other, may have a continuous structure, and there may be no visible or observable interface between the third sub-posts 520 and the second bridge pads 226. For example, the third sub-posts 520 and the second bridge pads 226 may be integrally formed of the same material and may be provided in the form of a single object. For example, the third sub-posts 520 and the second bridge pads 226 may be bonded to form a single object. The second semiconductor chip 500 may be electrically connected to the bridge die 220 through the third sub-posts 520, may be electrically connected to the capacitor 250 through the third sub-posts 520 and the penetration vias 240, and may be electrically connected to the redistribution substrate 100 through the fourth sub-posts 530 and the second conductive posts 330. The bridge die 220 may electrically connect the first semiconductor chip 400 to the second semiconductor chip 500.

According to an embodiment, a length of an electric connection path between the first and second semiconductor chips 400 and 500 and the bridge die 220 may be reduced. As a result, a semiconductor package with improved electrical characteristics may be provided. In addition, since the bridge pads 224 and 226 of the bridge die 220 of the bridge chip 200 are directly bonded to the first and third sub-posts 420 and 520, the semiconductor package may have improved structural stability.

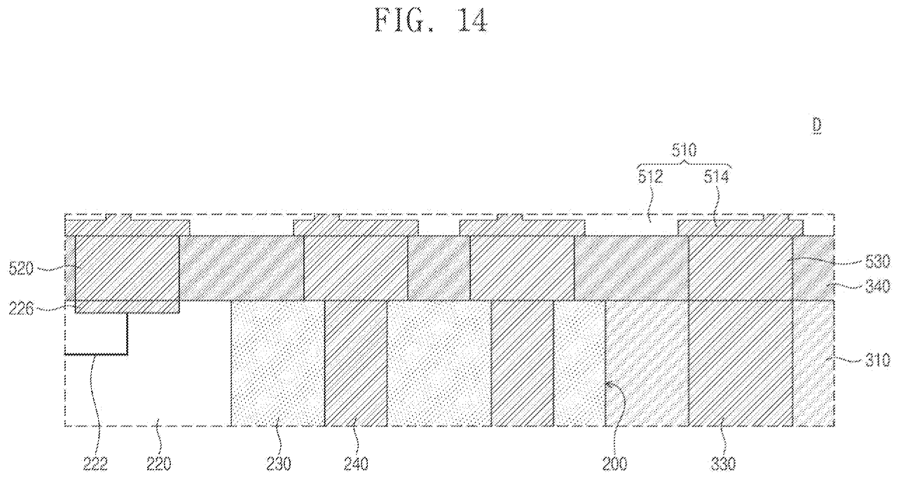

FIG. 15 is a sectional view illustrating a semiconductor package according to an embodiment of the inventive concept.

Referring to FIG. 15, a semiconductor package may further include a connection substrate 350, instead of the first and second conductive posts. The connection substrate 350 may be disposed on the redistribution substrate 100. The connection substrate 350 may have an opening OP, which is provided to penetrate the same. For example, the opening OP may have an opened-hole shape that extends from the top surface of the connection substrate 350 to the bottom surface. The opening OP may be placed on a center region of the redistribution substrate 100. The bottom surface of the connection substrate 350 may be in contact with the top surface of the redistribution substrate 100. The connection substrate 350 may be a vertical connection structure, which is disposed adjacent to or around the bridge chip 200 and is connected to the redistribution substrate 100.

The connection substrate 350 may include a base layer 352 and a conductive portion 354, which is an interconnection pattern provided in the base layer 352. In an embodiment, the base layer 352 may be formed of or include silicon oxide (SiO). The conductive portion 354 may be disposed in an outer portion of the connection substrate 350, which is located outside the opening OP.

The conductive portion 354 may include upper pads 355, vias 356, and lower pads 357. The upper pads 355 may be disposed in an upper portion of the connection substrate 350. The upper pads 355 may be exposed external to the connection substrate 350 near the top surface of the connection substrate 350. The lower pads 357 may be disposed in a lower portion of the connection substrate 350. The lower pads 357 may be exposed external to the connection substrate 350 near the bottom surface of the connection substrate 350. The lower pads 357 may be electrically connected to the redistribution substrate 100. For example, the first redistribution conductive pattern 120 of the redistribution substrate 100 may penetrate the first redistribution insulating layer 110 and may be connected to the lower pads 357. For example, the connection substrate 350 may serve as vertical connection terminals, which are configured to enable a vertical extension of an electric connection structure of the redistribution substrate 100 toward the first and second semiconductor chips 400 and 500. The vias 356 may be penetration electrodes, which are provided to penetrate the base layer 352 and are used to electrically connect the upper pads 355 to the lower pads 357.

The bridge chip 200 may be disposed in the opening OP of the connection substrate 350. The bridge chip 200 may have a planar area smaller than the opening OP, when viewed in a plan view. For example, the bridge chip 200 may be spaced apart from an inner surface of the opening OP.

Connection terminals 262, 264, 266, and 268 may further include third connection terminals 266, which are provided between the connection substrate 350 and the first semiconductor chip 400, and fourth connection terminals 268, which are provided between the connection substrate 350 and the second semiconductor chip 500.

The first mold layer 310 may be provided to fill a space between the connection substrate 350 and the bridge chip 200. For example, the first mold layer 310 may fill a remaining portion of the opening OP of the connection substrate 350. The first mold layer 310 may cover the top surface of the connection substrate 350 and the top surface of the bridge chip 200. The first mold layer 310 may be provided to enclose the connection terminals 262 and 264, and the top surfaces of the connection terminals 262 and 264 may be exposed external to the first mold layer 310 near the top surface of the first mold layer 310.

The first semiconductor chip 400 may be mounted on the bridge chip 200 and the first conductive posts 320 using the first and second sub-posts 420 and 430. For example, the first sub-posts 420 may connect the first chip interconnection pattern 414 to the first connection terminals 262, and the second sub-posts 430 may connect the first chip interconnection pattern 414 to the third connection terminals 266. The first semiconductor chip 400 may be electrically connected to the bridge die 220 through the first sub-posts 420, the first connection terminals 262, and the redistribution layer 210, may be electrically connected to the capacitor 250 through the first sub-posts 420, the first connection terminals 262, the redistribution layer 210, and the penetration vias 240, and may be electrically connected to the redistribution substrate 100 through the second sub-posts 430, the third connection terminals 266, and the connection substrate 350.

The second semiconductor chip 500 may be mounted on the bridge chip 200 and the second conductive posts 330 using the third and fourth sub-posts 520 and 530. For example, the third sub-posts 520 may connect the second chip interconnection pattern 514 to the second connection terminals 264, and the fourth sub-posts 530 may connect the second chip interconnection pattern 514 to the fourth connection terminals 268. The second semiconductor chip 500 may be electrically connected to the bridge die 220 through the third sub-posts 520, the second connection terminals 264, and the redistribution layer 210, may be electrically connected to the capacitor 250 through the third sub-posts 520, the second connection terminals 264, the redistribution layer 210, and the penetration vias 240, and may be electrically connected to the redistribution substrate 100 through the fourth sub-posts 530, the fourth connection terminals 268, and the connection substrate 350.

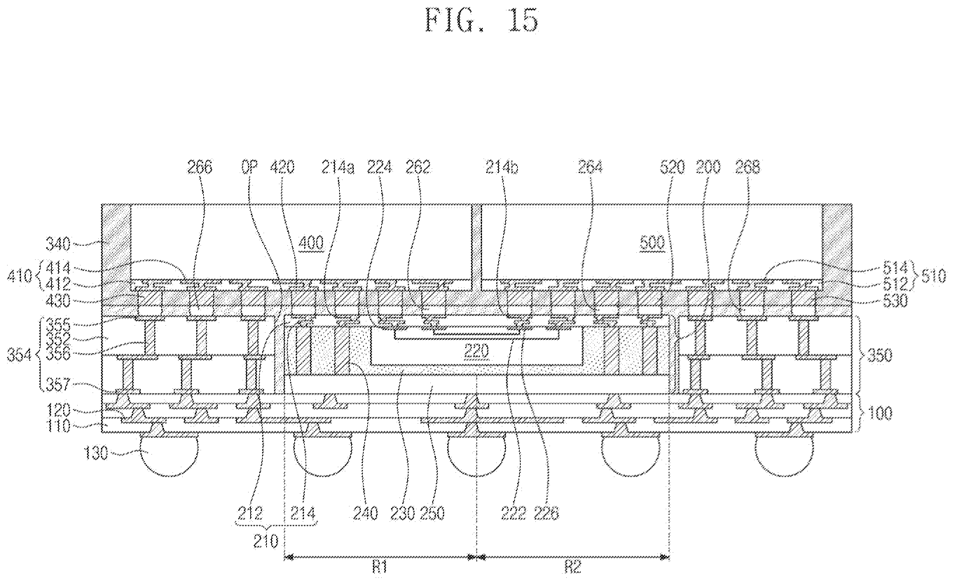

FIGS. 16 to 27 are sectional views illustrating a method of fabricating a semiconductor package, according to an embodiment.

Referring to FIG. 16, a first carrier substrate 910 may be provided. The first carrier substrate 910 may be an insulating substrate, which is formed of or includes glass or polymer, or a conductive substrate, which is formed of or includes at least one of metallic materials. An adhesive member may be provided on a top surface of the first carrier substrate 910. As an example, the adhesive member may include an adhesive tape.

The penetration vias 240 may be formed on the first carrier substrate 910. For example, the penetration vias 240 may be formed by depositing a sacrificial layer on the first carrier substrate 910, forming penetration holes vertically penetrating the sacrificial layer, and filling the penetration holes with a conductive material. Thereafter, the sacrificial layer may be removed.

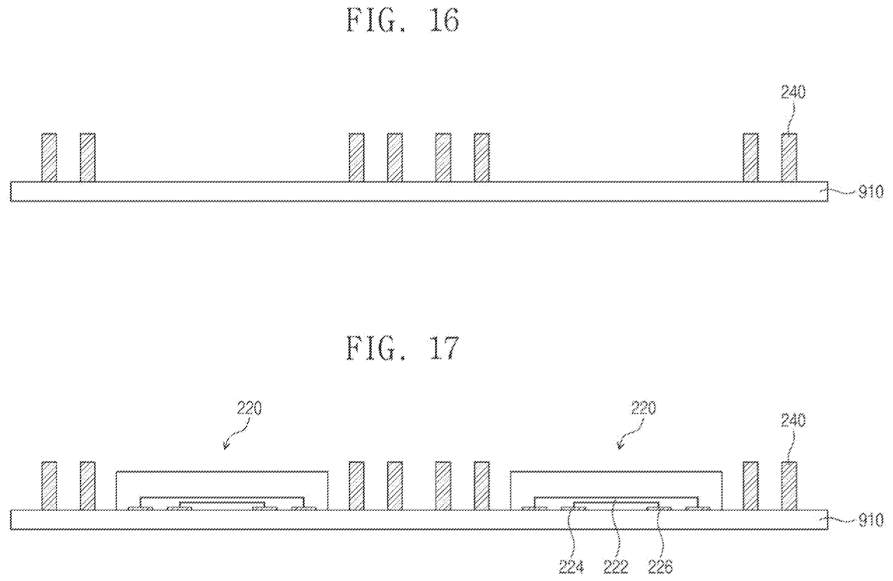

Referring to FIG. 17, the bridge dies 220 may be attached to the first carrier substrate 910. Each of the bridge dies 220 may be disposed between the penetration vias 240. The bridge dies 220 may be attached to the first carrier substrate 910 such that the first and second bridge pads 224 and 226 of the bridge die 220 face the first carrier substrate 910.

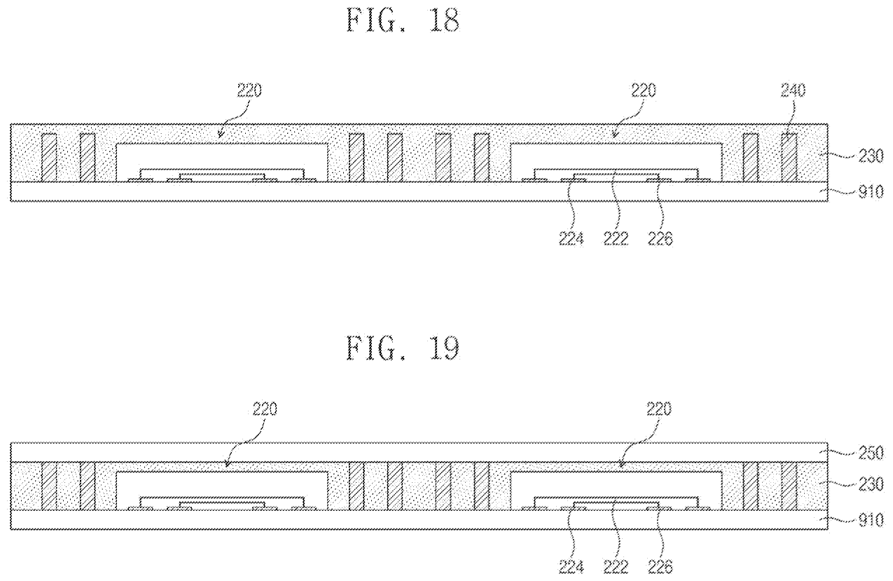

Referring to FIG. 18, the inner mold layer 230 may be formed on the first carrier substrate 910. For example, the inner mold layer 230 may be formed by forming an insulating material on the first carrier substrate 910 and curing the insulating material. The inner mold layer 230 may be formed on the first carrier substrate 910 to cover the bridge dies 220 and the penetration vias 240.

Referring to FIG. 19, a portion of the inner mold layer 230 may be removed. For example, a grinding or chemical mechanical polishing (CMP) process may be performed on the top surface of the inner mold layer 230. The grinding process or the chemical mechanical polishing process may be performed to expose top surfaces of the bridge dies 220 and top surfaces of the penetration vias 240. Thus, a portion of the inner mold layer 230, which is placed on the top surfaces of the bridge dies 220 and the top surfaces of the penetration vias 240, may be removed. The top surface of the inner mold layer 230, the top surface of the bridge die 220, and the top surfaces of the penetration vias 240 may be substantially flat and may be substantially coplanar with each other.

Next, the capacitor 250 may be formed on the inner mold layer 230. The first and second capacitor pads 254 and 255 (e.g., see FIGS. 2 and 3) of the capacitor 250 may be connected to the penetration vias 240.

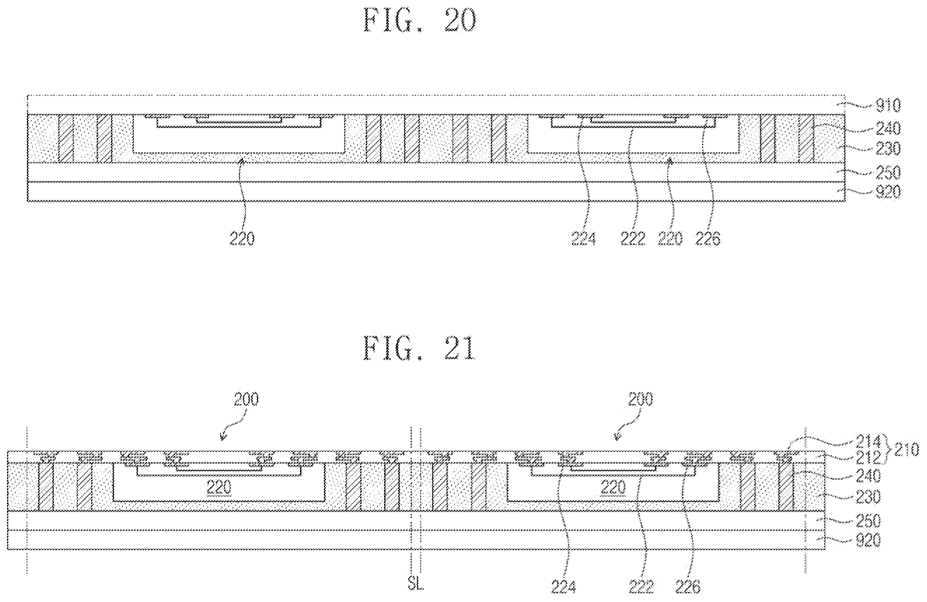

Referring to FIG. 20, a second carrier substrate 920 may be attached to the capacitor 250. The second carrier substrate 920 may be an insulating substrate, which is formed of or includes glass or polymer, or a conductive substrate, which is formed of or includes at least one of metallic materials. An adhesive member may be provided on a top surface of the second carrier substrate 920. As an example, the adhesive member may include an adhesive tape. The second carrier substrate 920 may be attached to the capacitor 250 using the adhesive member.

Thereafter, the afore-described structure may be inverted such that the second carrier substrate 920 is placed on the first carrier substrate 910. Thereafter, the first carrier substrate 910 may be removed. Accordingly, the top surface of the bridge die 220, the top surface of the penetration vias 240, and the top surface of the inner mold layer 230 may be exposed to the outside. As an example, the first and second bridge pads 224 and 226 of the bridge die 220 may be exposed to the outside.

Referring to FIG. 21, the redistribution layer 210 may be formed on the inner mold layer 230. For example, an insulating layer may be formed on the inner mold layer 230 and then may be patterned to expose the penetration vias 240 and the first and second bridge pads 224 and 226, and a conductive layer may be formed on the insulating layer and may be patterned to form a conductive pattern. Thereafter, a process of forming the insulating layer and the conductive pattern may be repeatedly performed to form the redistribution layer 210 including the second redistribution insulating layer 212 and the second redistribution conductive patterns 214. As a result of the above process, the bridge chips 200 may be formed to include the redistribution layer 210, the bridge die 220, the inner mold layer 230, the penetration vias 240, and the capacitor 250.

When, as in the embodiment of FIGS. 9 and 13, the bridge chip 200 does not have the redistribution layer 210, the process of forming the redistribution layer 210 may be omitted.

Next, a singulation process may be performed on the redistribution layer 210, the inner mold layer 230, and the capacitor 250 along a sawing line SL to form the bridge chips 200, which are separated from each other. For example, the redistribution layer 210, the inner mold layer 230, and the capacitor 250 may be sequentially cut by the singulation process. Here, the sawing line SL may be placed between the bridge dies 220, and the bridge dies 220 may not be cut by the singulation process.

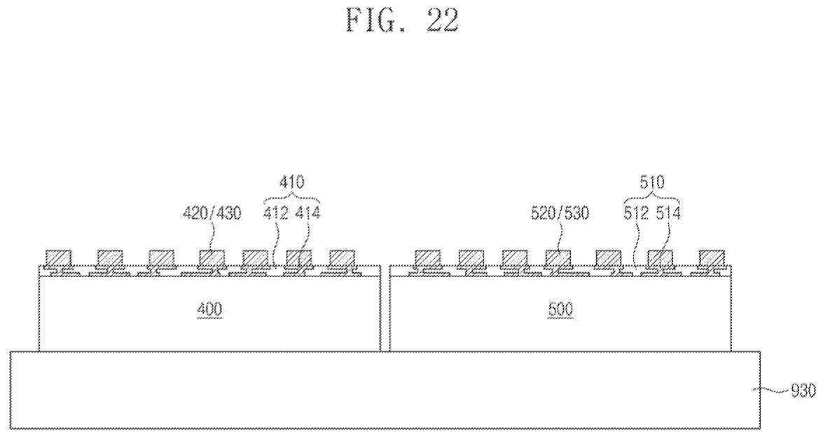

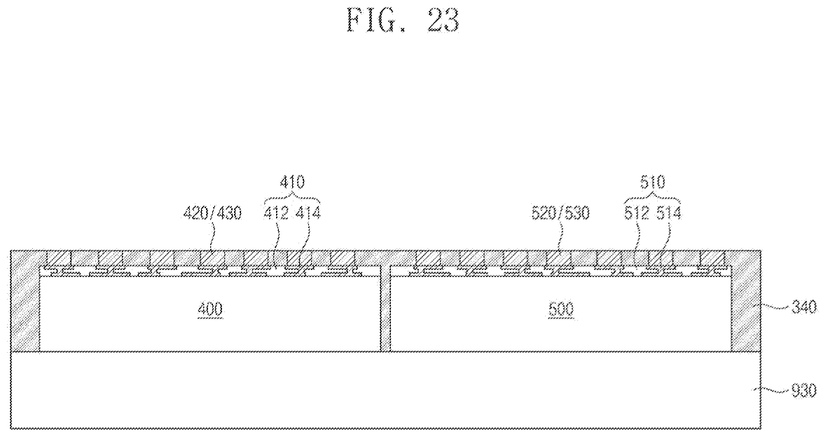

Referring to FIG. 22, a third carrier substrate 930 may be provided. The third carrier substrate 930 may be an insulating substrate, which is formed of or includes glass or polymer, or a conductive substrate, which is formed of or includes at least one of metallic materials. An adhesive member may be provided on a top surface of the third carrier substrate 930. As an example, the adhesive member may include an adhesive tape.

The first and second semiconductor chips 400 and 500 may be attached to the third carrier substrate 930. The first and second semiconductor chips 400 and 500 may be provided to have substantially the same or similar features as the first and second semiconductor chips 400 and 500 described with reference to FIGS. 1 to 15. The first and second semiconductor chips 400 and 500 may be disposed on the third carrier substrate 930 to be horizontally spaced apart from each other.

The sub-posts 420, 430, 520, and 530 may be formed on the first and second semiconductor chips 400 and 500. For example, the first and second sub-posts 420 and 430 on the first semiconductor chip 400 and the third and fourth sub-posts 520 and 530 on the second semiconductor chip 500 may be formed by depositing a sacrificial layer on the first and second semiconductor chips 400 and 500, forming trenches in the sacrificial layer to expose the first chip interconnection pattern 414 of the first semiconductor chip 400 and the second chip interconnection pattern 514 of the second semiconductor chip 500, and filling the trenches with a conductive material.

Referring to FIG. 23, the second mold layer 340 may be formed on the third carrier substrate 930. For example, the second mold layer 340 may be formed by forming an insulating material on the third carrier substrate 930 and curing the insulating material. The second mold layer 340 may cover the first and second semiconductor chips 400 and 500 and the sub-posts 420, 430, 520, and 530.

Thereafter, a portion of the second mold layer 340 may be removed. In detail, a grinding or CMP process may be performed on a top surface of the second mold layer 340. The grinding process or the chemical mechanical polishing process may be performed to expose top surfaces of the sub-posts 420, 430, 520, and 530. Accordingly, a portion of the second mold layer 340, which is placed on the top surfaces of the sub-posts 420, 430, 520, and 530, may be removed. The top surface of the second mold layer 340 and the top surfaces of the sub-posts 420, 430, 520, and 530 may be substantially flat and may be substantially coplanar with each other.

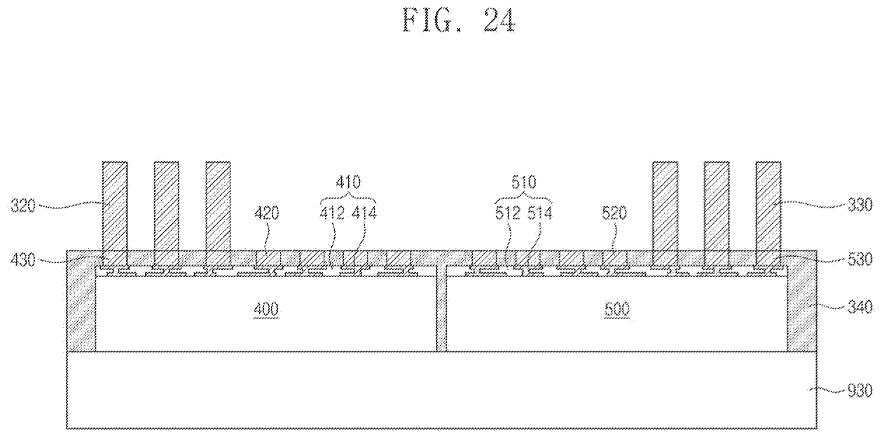

Referring to FIG. 24, the first and second conductive posts 320 and 330 may be formed on the second mold layer 340. For example, the first and second conductive posts 320 and 330 may be formed on the second and fourth sub-posts 430 and 530, respectively, by depositing a sacrificial layer on the second mold layer 340, forming trenches in the sacrificial layer to expose the second sub-posts 430 and the fourth sub-posts 530, and filling the trenches with a conductive material. Thereafter, the sacrificial layer may be removed.

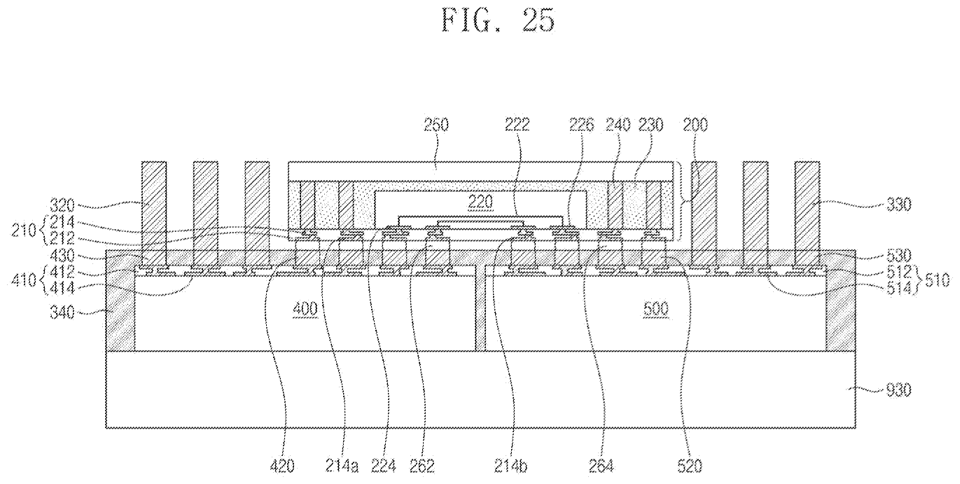

Referring to FIG. 25, the bridge chip 200 may be mounted on the first and second semiconductor chips 400 and 500. The bridge chip 200 may be mounted on the first and second semiconductor chips 400 and 500 in a flip chip manner. For example, the first connection terminals 262 may be provided on the first pads 214a of the bridge chip 200, and the second connection terminals 264 may be provided on the second pads 214b. The bridge chip 200 may be aligned to the second mold layer 340 to place the first connection terminals 262 on the first sub-posts 420 and place the second connection terminals 264 on the third sub-posts 520. Thereafter, a reflow process may be performed to bond the first connection terminals 262 to the first sub-posts 420 and to bond the second connection terminals 264 to the third sub-posts 520.

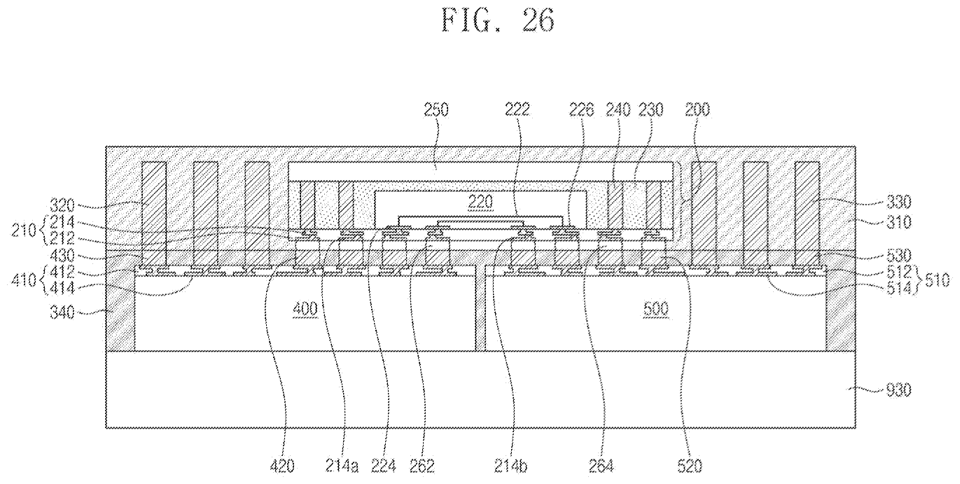

Referring to FIG. 26, the first mold layer 310 may be formed on the second mold layer 340. For example, the first mold layer 310 may be formed by forming an insulating material on the second mold layer 340 and curing the insulating material. The first mold layer 310 may cover the first and second conductive posts 320 and 330 and the bridge chip 200.

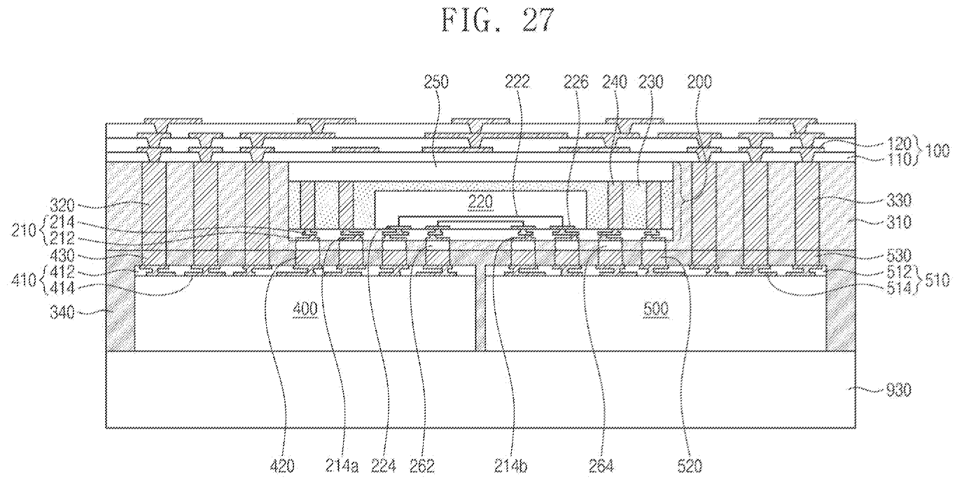

Referring to FIG. 27, a portion of the first mold layer 310 may be removed. For example, a grinding or CMP process may be performed on the top surface of the first mold layer 310. The grinding process or the chemical mechanical polishing process may be performed to expose top surfaces of the first and second conductive posts 320 and 330 and the top surface of the bridge chip 200. Accordingly, a portion of the first mold layer 310, which is placed on the top surfaces of the first and second conductive posts 320 and 330 and the top surface of the bridge chip 200, may be removed. The top surface of the first mold layer 310, the top surfaces of the first and second conductive posts 320 and 330, and the top surface of the bridge chip 200 may be substantially flat and may be substantially coplanar with each other.

The redistribution substrate 100 may be formed on the first mold layer 310. For example, an insulating layer may be formed on the first mold layer 310, the bridge chip 200, and the first and second conductive posts 320 and 330. The first redistribution insulating layer 110 may be formed by patterning the insulating layer to form openings exposing the first and second conductive posts 320 and 330. A conductive layer may be formed on the first redistribution insulating layer 110. The conductive layer may be formed to fill an opening of the first redistribution insulating layer 110 and cover the first redistribution insulating layer 110. Thereafter, the conductive layer may be patterned to form the first redistribution conductive pattern 120. The afore-described process of forming the first redistribution insulating layer 110 and the first redistribution conductive pattern 120 may be repeatedly performed to form the redistribution substrate 100.

When the capacitor 250 has the third capacitor pads 256 in the embodiment of FIGS. 6 to 8, the first redistribution conductive pattern 120 of the redistribution substrate 100 may be connected to the third capacitor pads 256.

Referring back to FIG. 1, the outer terminals 130 may be provided on the first redistribution conductive pattern 120, which is exposed near or on a surface of the redistribution substrate 100.

Thereafter, the semiconductor package described with reference to FIG. 1 may be fabricated by removing the third carrier substrate 930.

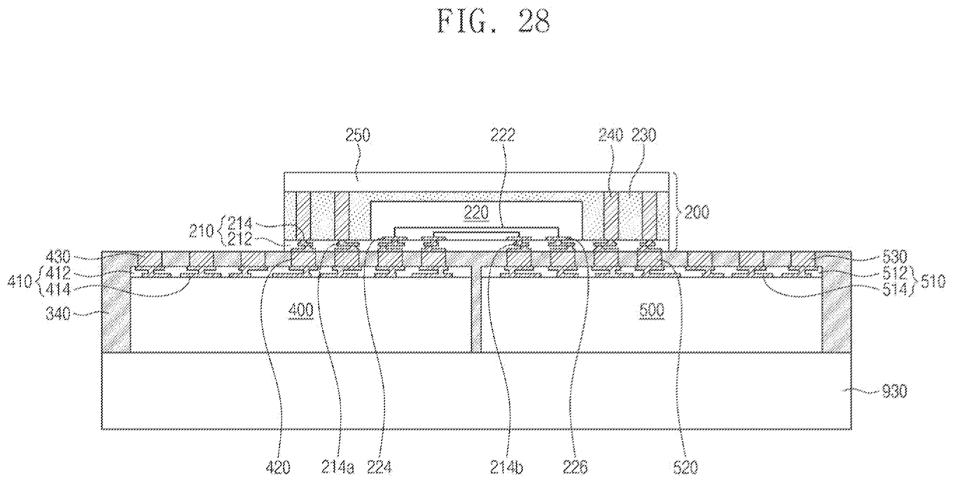

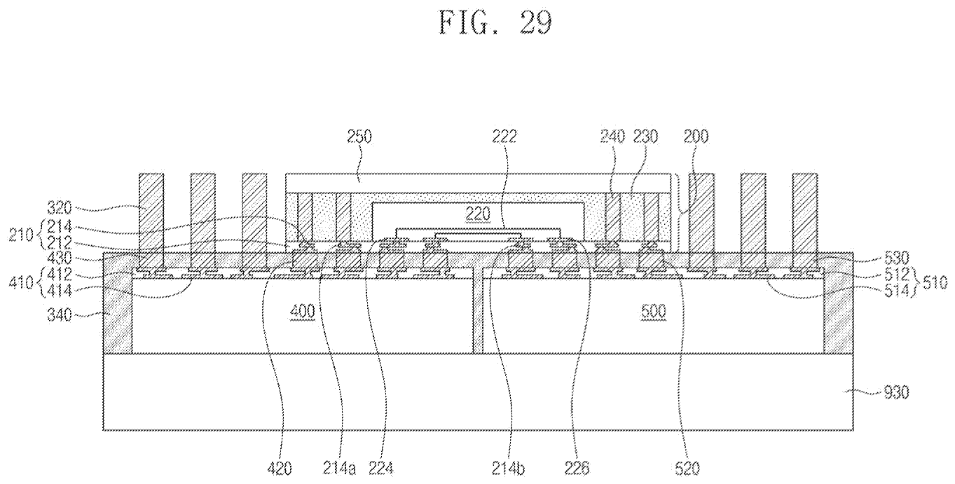

FIGS. 28 and 29 are sectional views illustrating a method of fabricating a semiconductor package, according to an embodiment.

Referring to FIG. 28, the bridge chip 200 may be mounted on the first and second semiconductor chips 400 and 500 in the resulting structure of FIG. 23. The bridge chip 200 may be aligned to the second mold layer 340 to place the first pads 214a of the bridge chip 200 on the first sub-posts 420 and place the second pads 214b of the bridge chip 200 on the third sub-posts 520. The bridge chip 200 may be disposed on the second mold layer 340 such that the first pads 214a are in contact with the first sub-posts 420 and the second pads 214b are in contact with the third sub-posts 520. A thermal treatment process may be performed on the bridge chip 200. As a result of the thermal treatment process, the first pads 214a may be bonded to the first sub-posts 420, and the second pads 214b may be bonded to each other the third sub-posts 520. For example, the first pads 214a may be bonded to the first sub-posts 420 to form a single object, and the second pads 214b may be bonded to the third sub-posts 520 to form a single object. The first and second pads 214a and 214b may be spontaneously bonded to the first and third sub-posts 420 and 520. In detail, the first and second pads 214a and 214b and the first and third sub-posts 420 and 520 may be formed of the same material (e.g., copper (Cu)), and the first and second pads 214a and 214b may be bonded to the first and third sub-posts 420 and 520 by an inter-metal hybrid bonding process caused by a surface activation phenomenon at interfaces of the first and second pads 214a and 214b and the first and third sub-posts 420 and 520, which are in contact with each other. The first and second pads 214a and 214b may be bonded to the first and third sub-posts 420 and 520 by the thermal treatment process.

Referring to FIG. 29, the first and second conductive posts 320 and 330 may be formed on the second mold layer 340. For example, the first and second conductive posts 320 and 330 may be formed on the second and fourth sub-posts 430 and 530, respectively, by depositing a sacrificial layer on the second mold layer 340, forming trenches in the sacrificial layer to expose the second sub-posts 430 and the fourth sub-posts 530, and filling the trenches with a conductive material. Thereafter, the sacrificial layer may be removed.

Next, the process described with reference to FIGS. 26 to 28 may be performed to form the first mold layer 310 on the second mold layer 340 and the redistribution substrate 100 on the first mold layer 310.

Referring back to FIG. 11, the outer terminals 130 may be provided on the first redistribution conductive pattern 120, which is exposed near a surface of the redistribution substrate 100.

Thereafter, the semiconductor package described with reference to FIG. 11 may be fabricated by removing the third carrier substrate 930.

According to an embodiment, it may be unnecessary to provide an additional space, in which a capacitor is placed, in a semiconductor package. For example, it may be possible to reduce a size of the semiconductor package. Furthermore, electric connection paths between a bridge die, a capacitor, and semiconductor chips may be shortened, and this may make it possible to improve the electrical characteristics of the semiconductor package. In addition, a bridge chip may be directly bonded to sub-posts, and in this case, it may be possible to improve the structural stability of the semiconductor package.

While example embodiments have been particularly shown and described, it will be understood by one of ordinary skill in the art that variations in form and detail may be made therein without departing from the spirit and scope of the attached claims and their equivalents.

What is claimed is:

1. A semiconductor package, comprising:
a redistribution substrate;
a bridge chip on the redistribution substrate;
a first conductive post and a second conductive post on the redistribution substrate and spaced apart from the bridge chip;
a first semiconductor chip on the bridge chip and the first conductive post;
a second semiconductor chip on the bridge chip and the second conductive post; and
a first mold layer on the redistribution substrate, the bridge chip, the first semiconductor chip, and the second semiconductor chip,
wherein the bridge chip comprises:
a bridge die connected to an active surface of the first semiconductor chip and an active surface of the second semiconductor chip;
a second mold layer on the bridge die;
a penetration via adjacent to the bridge die and vertically penetrating the second mold layer; and
a capacitor disposed a bottom surface of the second mold layer and connected to the penetration via.

2. The semiconductor package of claim 1, wherein the capacitor comprises:
a first electrode on the bottom surface of the second mold layer;
a second electrode vertically spaced apart from the first electrode; and
a high-k dielectric layer between the first electrode and the second electrode.

3. The semiconductor package of claim 1, wherein the first mold layer comprises:
a first sub-mold layer on the redistribution substrate, the first conductive post, the second conductive post, and the bridge chip; and
a second sub-mold layer on the first sub-mold layer, the first semiconductor chip, and the second semiconductor chip.

4. The semiconductor package of claim 3, wherein the first semiconductor chip comprises a first sub-post and a second sub-post, the first sub-post and the second sub-post being on the active surface of the first semiconductor chip,
wherein the second semiconductor chip comprises a third sub-post and a fourth sub-post, the third sub-post and the fourth sub-post being on the active surface of the second semiconductor chip,
wherein the first sub-post connects the first conductive post to the first semiconductor chip,
wherein the second sub-post connects the bridge die of the bridge chip to the first semiconductor chip,
wherein the third sub-post connects the second conductive post to the second semiconductor chip, and
wherein the fourth sub-post connects the bridge die of the bridge chip to the second semiconductor chip.

5. The semiconductor package of claim 4, wherein the second sub-mold layer is on the first sub-post, the second sub-post, the third sub-post, and the fourth sub-post, and
wherein a bottom surface of each of the first sub-post, the second sub-post, the third sub-post, and fourth sub-post is coplanar with a bottom surface of the second sub-mold layer.

6. The semiconductor package of claim 4, wherein the penetration via and a conductive pattern of the bridge die directly contact the second sub-post and the fourth sub-post.

7. The semiconductor package of claim 3, wherein a top surface of the first sub-mold layer is coplanar with a top surface of the first conductive post, a top surface of the second conductive post, and a top surface of the bridge chip.

8. The semiconductor package of claim 1, wherein the bridge chip further comprises bumps on a top surface of the bridge die, and
wherein the bumps are between the bridge die of the bridge chip and each of the first semiconductor chip and the second semiconductor chip.

9. The semiconductor package of claim 1, wherein the bridge chip directly contacts a top surface of the redistribution substrate, and
wherein a conductive pattern of the redistribution substrate is connected to the capacitor of the bridge chip.

10. The semiconductor package of claim 1, wherein the bridge chip further comprises a redistribution layer on the bridge die and the second mold layer,
wherein the redistribution layer is connected to the bridge die and the penetration via, and
wherein the first semiconductor chip and the second semiconductor chip are electrically connected to the redistribution layer of the bridge chip.

11. A semiconductor package, comprising:
a redistribution substrate;
a bridge chip on the redistribution substrate;
a first semiconductor chip and a second semiconductor chip on the bridge chip, each of the first semiconductor chip and the second semiconductor chip being shifted from the bridge chip horizontally such that a portion of an active surface of the bridge chip is exposed; and
vertical connection terminals horizontally spaced apart from the bridge chip and connecting the first semiconductor chip and the second semiconductor chip to the redistribution substrate,
wherein the bridge chip comprises:
a redistribution layer on an active surface of the first semiconductor chip and an active surface of the second semiconductor chip;
a bridge die on a bottom surface of the redistribution layer;
a first mold layer on the bottom surface of the redistribution layer and the bridge die;
a capacitor on a bottom surface of the first mold layer; and
a penetration via vertically penetrating the first mold layer and connecting the redistribution layer to the capacitor.

12. The semiconductor package of claim 11, wherein the vertical connection terminals comprise:
first posts adjacent to a first side of the bridge chip and connecting the redistribution substrate to the first semiconductor chip; and
second posts adjacent to a second side of the bridge chip and connecting the redistribution substrate to the second semiconductor chip.

13. The semiconductor package of claim 11, further comprising a connection substrate on the redistribution substrate,
wherein the connection substrate comprises an opening,
wherein the bridge chip is in the opening of the connection substrate, and
wherein the vertical connection terminals comprise conductive patterns in the connection substrate.

14. The semiconductor package of claim 11, further comprising:
a second mold layer on the redistribution substrate, the bridge chip; and
a third mold layer on the second mold layer, the first semiconductor chip and the second semiconductor chip.

15. The semiconductor package of claim 14, wherein the first semiconductor chip comprises a first sub-post and a second sub-post, the first sub-post and the second sub-post being on the active surface of the first semiconductor chip,
wherein the second semiconductor chip comprises a third sub-post and a fourth sub-post, the third sub-post and the fourth sub-post being on the active surface of the second semiconductor chip,
wherein the first sub-post and the third sub-post are electrically connected to the vertical connection terminals,
wherein the second sub-post and the fourth sub-post are electrically connected to the bridge chip,
wherein the third mold layer is on the first sub-post, the second sub-post, the third sub-post, and the fourth sub-post, and
wherein bottom surfaces of the first sub-post, the second sub-post, the third sub-post, and fourth sub-post are coplanar with a bottom surface of the third mold layer.

16. The semiconductor package of claim 15, wherein a conductive pattern of the bridge die directly contacts the second sub-post and the fourth sub-post.

17. The semiconductor package of claim 11, wherein the capacitor comprises:
a first electrode on the bottom surface of the first mold layer;
a second electrode vertically spaced apart from the first electrode; and
a high-k dielectric layer between the first electrode and the second electrode.

18. The semiconductor package of claim 11, wherein the bridge chip further comprises bumps on an active surface of the bridge die, and
wherein a bump is between the bridge die of the bridge chip and each of the first semiconductor chip and the second semiconductor chip.

19. The semiconductor package of claim 11, wherein the bridge chip directly contacts a top surface of the redistribution substrate, and
wherein a conductive pattern of the redistribution substrate is connected to the capacitor of the bridge chip.

20. A semiconductor package, comprising:
a first semiconductor chip and a second semiconductor chip horizontally spaced apart from each other;
first sub-posts on a top surface of the first semiconductor chip and connected to the first semiconductor chip;
second sub-posts on a top surface of the second semiconductor chip and connected to the second semiconductor chip;
a first mold layer on the first semiconductor chip, the second semiconductor chip, the first sub-posts, and the second sub-posts;
a bridge chip on the first mold layer, a portion of the first sub-posts, and a portion of the second sub-posts;
a second mold layer on the first mold layer and the bridge chip;
a redistribution substrate on the second mold layer and the bridge chip;
first posts vertically penetrating the second mold layer and connecting a remaining portion of the first sub-posts to the redistribution substrate; and
second posts vertically penetrating the second mold layer and connecting a remaining portion of the second sub-posts to the redistribution substrate,
wherein the bridge chip comprises:
a bridge die connected to a portion of the first sub-posts and a portion of the second sub-posts;
a capacitor on the bridge die; and
a penetration via vertically connected to the capacitor and adjacent to the bridge die.
